(19) United States
(12) Patent Application Publication
(10) Pub. No.: US 2025/0351537 A1
(43) Pub. Date: Nov. 13, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Tefu YEH, Kaohsiung City (TW); Jo-Chun HUNG, Hsinchu City (TW); Ying-Liang CHUANG, Zhubei City (TW)

(21) Appl. No.: 18/659,212

(22) Filed: May 9, 2024

(51) Int. Cl. H01L 21/8238; H01L 27/092; H01L 29/06; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 62/121; H10D 64/015; H10D 84/0177; H10D 84/85

(57) ABSTRACT

Sacrificial spacers are formed between vertically adjacent nanostructure channels of a first nanostructure transistor to prevent or reduce the likelihood of material from a work function metal layer of a second nanostructure transistor being deposited between the vertically adjacent nanostructure channels. A sacrificial spacer layer is formed around the nanostructure channels of the first nanostructure channel and then etched such that the sacrificial spacer layer remains only between vertically adjacent nanostructure channels of the first nanostructure transistor as the sacrificial spacers. An anisotropic wet etch technique is used to etch the sacrificial spacer layer such that seams in the sacrificial spacer layer are not widened by the etching. This increases the likelihood that the material of the work function metal layer of the second nanostructure transistor will be fully removed from the first nanostructure transistor prior to formation of a work function metal layer of the second nanostructure transistor.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a fin definition process described herein.

FIG. 2 is a diagram of an example dummy gate structure formation process described herein.

FIG. 3 is a diagram of an example implementation of a source/drain recess formation process described herein.

FIGS. 4A and 4B are diagrams of an example implementation of an inner spacer formation process described herein.

FIG. 5 is a diagram of an example implementation of a source/drain region formation process described herein.

FIG. 6 is a diagram of an example implementation of an interlayer dielectric formation process described herein.

FIGS. 7A-7P are diagrams of an example implementation of a replacement gate process described herein.

FIG. 8 is a diagram of examples of corner rounding in nanostructure channels of a semiconductor device described herein.

FIGS. 9 and 10 are flowcharts of example processes associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A nanostructure transistor may include a gate structure that wraps around a plurality of nanostructure channels. The gate structure wrapping around the nanostructure channels increases control of the gate structure over a conductive channel in the nanostructure channels, increases drive current for the nanostructure transistor, and/or may reduce short channel effects (SCEs) for the nanostructure transistor, among other examples. In some cases, a semiconductor device may include p-type metal oxide semiconductor (PMOS) nanostructure transistors and n-type metal oxide semiconductor (NMOS) nanostructure transistors. Integrating PMOS nanostructure transistors and NMOS nanostructure transistors into the same semiconductor device enables complementary metal oxide semiconductor (CMOS) integrated circuits to be realized in the semiconductor device. CMOS integrated circuits have many use cases in the semiconductor industry, including microprocessors (e.g., central processing units (CPUs)), graphics processing units (GPUs)), memory devices, digital logic circuitry, image sensors (e.g., CMOS image sensors), and/or radio frequency (RF) circuitry, among other examples.

The threshold voltage (Vₜ) for a nanostructure transistor is the required gate voltage to selectively turn the nanostructure transistor on or off. If the threshold voltage for the nanostructure transistor is too low (meaning that the gate voltage for activating the nanostructure transistor is too low), the nanostructure transistor may experience a high amount of current leakage when the nanostructure transistor is off. Conversely, if the threshold voltage for the nanostructure transistor is too high, the power efficiency of the nanostructure transistor may be degraded because higher gate voltages are needed to operate the nanostructure transistor. For PMOS nanostructure transistors and NMOS nanostructure transistors, the types of metals that are used for the gate structures may directly impact the threshold voltages for the PMOS nanostructure transistors and the NMOS nanostructure transistors. Metals that tune the work function (φₘ) of a gate structure for optimal performance of a PMOS nanostructure transistor may result in a large band gap between the work function of a gate structure of an NMOS nanostructure transistor and the conduction band (E_{C}), resulting in a high threshold voltage (and low power efficiency) for the NMOS nanostructure transistor. Metals that tune the work function of a gate structure for optimal performance of an NMOS nanostructure transistor may result in a large band gap between the work function of a gate structure of a PMOS nanostructure transistor and the valance band (E_{V}), resulting in a high threshold voltage (and low power efficiency) for the PMOS nanostructure transistor.

In some cases, work function metal layers for PMOS and NMOS nanostructure transistors may be formed in a sequential manner. For example, the work function metal layer(s) for a PMOS nanostructure transistor may be formed first, followed by formation of the work function metal layer(s) for an NMOS nanostructure transistor. The work function metal layer(s) for a PMOS nanostructure transistor may be formed around nanostructure channels for both the PMOS nanostructure transistor and the NMOS nanostructure transistor, and work function metal layer(s) for a PMOS nanostructure transistor may be subsequently removed from the nanostructure channels of the NMOS nanostructure transistor, prior to formation of the work function metal layer(s) for the NMOS nanostructure transistor. However, residual material from the work function metal layer(s) for a PMOS nanostructure transistor may remain on the nanostructure channels of the NMOS nanostructure transistor, such as between vertically adjacent nanostructure channels. This residual material may result in suboptimal performance of the NMOS nanostructure transistor in that the residual material may alter threshold voltage of the NMOS nanostructure transistor.

In some implementations described herein, sacrificial spacers are formed between vertically adjacent nanostructure channels of a first nanostructure transistor to prevent or reduce the likelihood of material from a work function metal layer of a second nanostructure transistor being deposited between the vertically adjacent nanostructure channels. In this way, the sacrificial spacers increase the likelihood that the material of the work function metal layer of the second nanostructure transistor will be fully removed from the first nanostructure transistor prior to formation of a work function metal layer of the second nanostructure transistor.

The sacrificial spacers may be formed by depositing a conformal sacrificial spacer layer around the nanostructure channels of the first nanostructure channel, and then etching the sacrificial spacer layer such that the sacrificial spacer layer remains only between vertically adjacent nanostructure channels of the first nanostructure transistor as the sacrificial spacers. In some cases, seams may form in the sacrificial spacer layer between vertically adjacent nanostructure channels. An anisotropic wet etch technique described herein may be used to etch the sacrificial spacer layer such that the seams are not widened (or are minimally widened) by the etching, which might otherwise increase the likelihood of the material of the work function metal layer of the second nanostructure transistor being deposited in the seams between the vertically adjacent nanostructure channels. Thus, the anisotropic wet etch technique described herein may increase the likelihood that the material of the work function metal layer of the second nanostructure transistor will be fully removed from the first nanostructure transistor prior to formation of a work function metal layer of the second nanostructure transistor.

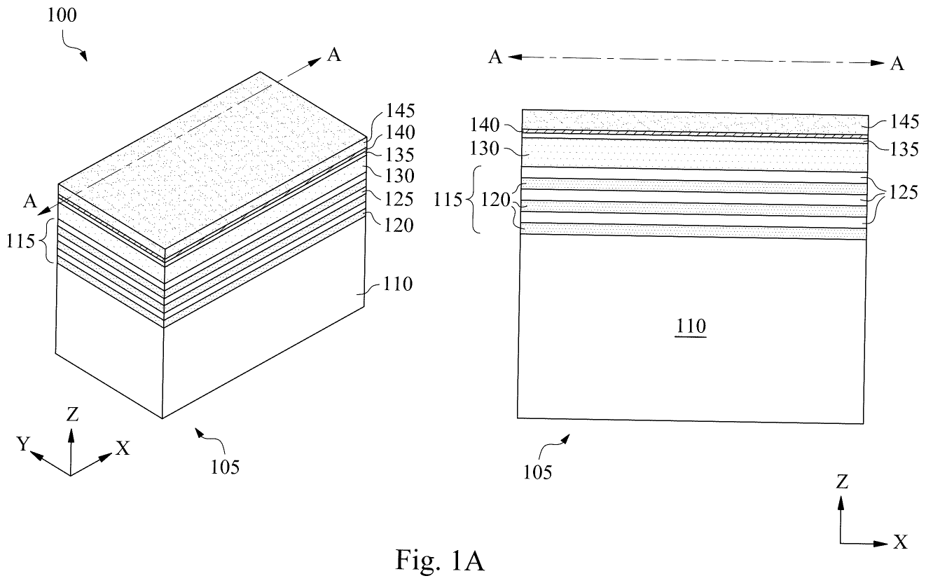

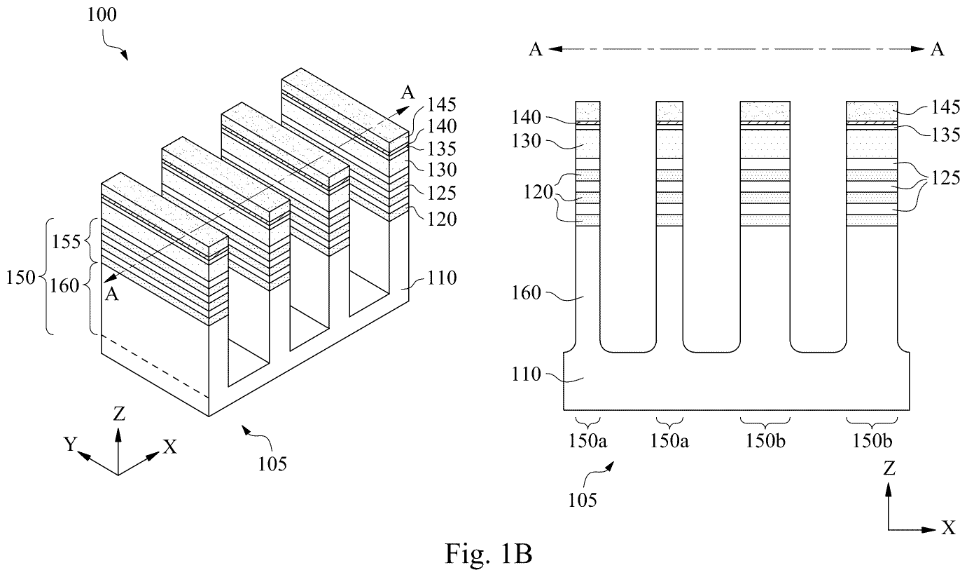

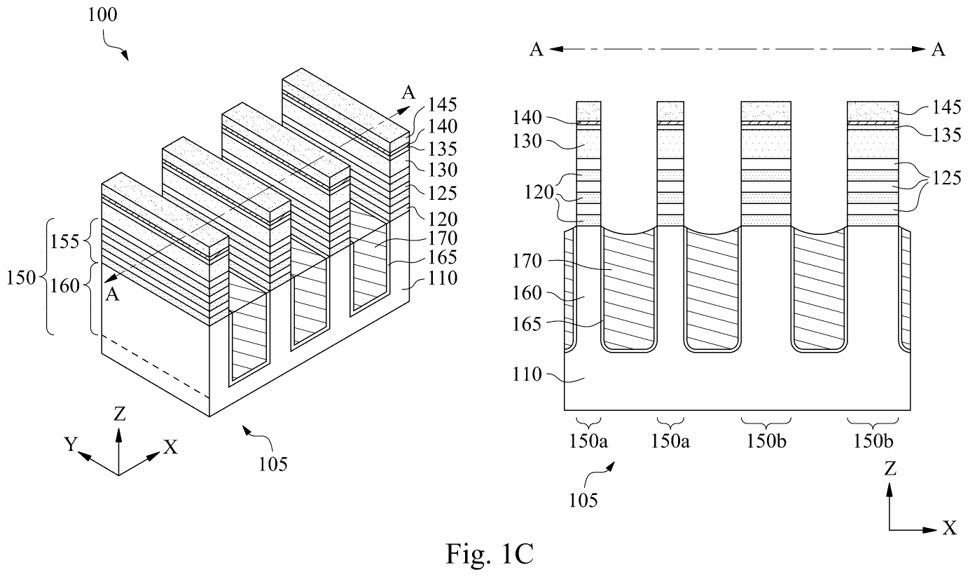

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1C each illustrate a perspective view of the semiconductor device 105 and a cross-sectional view along the line A-A in the perspective view. As shown in FIGS. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

One or more masking layers may be form (e.g., using one or more deposition tools) on the layer stack 115. The masking layer(s) may include a hard mask (HM) layer 130, a capping layer 135, an oxide layer 140, and/or a nitride layer 145. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 150 that extend above the semiconductor substrate 110. The fin structures 150 may extend in a y-direction in the semiconductor device 105 and may be arranged in an x-direction in the semiconductor device 105. A fin structure 150 includes a portion 155 of the layer stack 115 over and/or on a fin portion 160 above the semiconductor substrate 110. The fin structures 150 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 150 may be formed to have different widths for different types of nanostructure transistors. As an example, a first subset of fin structures 150a may be formed for p-type nanostructure transistors (e.g., p-type metal oxide semiconductor (PMOS) nanostructure transistors), and a second subset of fin structures 150b may be formed for n-type nanostructure transistors (e.g., n-type metal oxide semiconductor (NMOS) nanostructure transistors). As another example, a first subset of fin structures 150a may be formed for nanostructure transistors that are configured to operate at lower voltages, and a second subset of fin structures 150b may be formed for nanostructure transistors that are configured to operate at higher voltages.

As shown in FIG. 1C, a liner 165 and STI regions 170 are formed between adjacent fin portions 160 of the fin structures 150. The liner 165 and the STI regions 170 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

A deposition tool may be used to conformally deposit the liner (e.g., using ALD or another conformal deposition technique), and may deposit a dielectric layer (e.g., using CVD, PVD, a ALD, and/or another suitable deposition technique) on the liner 165 such that the dielectric layer fully fills in the spaces between the fin structures 150 and extends above the tops of the fin structures 150. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 145. The nitride layer 145 functions as a CMP stop layer in the planarization operation. An etch tool may be used to then etch the dielectric layer to form the STI regions 170 such that the top surfaces of the STI region 170 are approximately co-planar with or below the bottom-most sacrificial nanostructure layer 120.

As indicated above, FIGS. 1A-1C are provided as an example. Other examples may differ from what is described with regard to FIGS. 1A-1C.

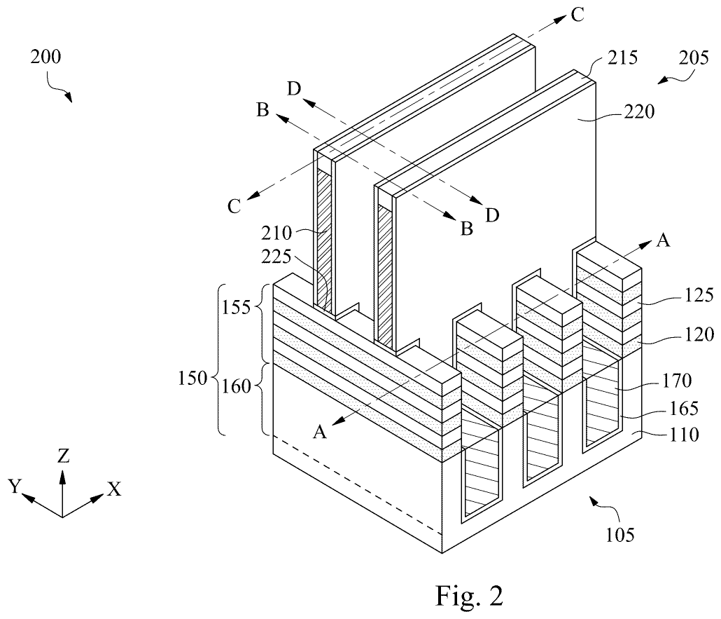

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 200 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 150 and portions of the STI regions 170. The dummy gate structures 205 extend in the x-direction and are arranged in the y-direction such that the dummy gate structures 205 are approximately perpendicular to the fin structures 150. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 150.

A dummy gate structure 205 may include a gate electrode layer 210, a hard mask layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The hard mask layer 215 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an x-z plane (referred to as a y-cut) across the fin structures 150 in the source/drain areas of the semiconductor device 105. Cross-section B-B is in a y-z plane (referred to as an x-cut) perpendicular to the cross-section A-A, and is across the dummy gate structures 205 and along an underlying fin structure 150. Cross-section C-C is in the x-z plane parallel to the cross-section A-A and perpendicular to the cross-section B-B, and is along a dummy gate structure 205. Cross-section D-D is in a y-z plane (referred to as an x-cut) perpendicular to the cross-section A-A, and is across the dummy gate structures 205 and along an underlying STI region 170 between adjacent fin structures 150. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

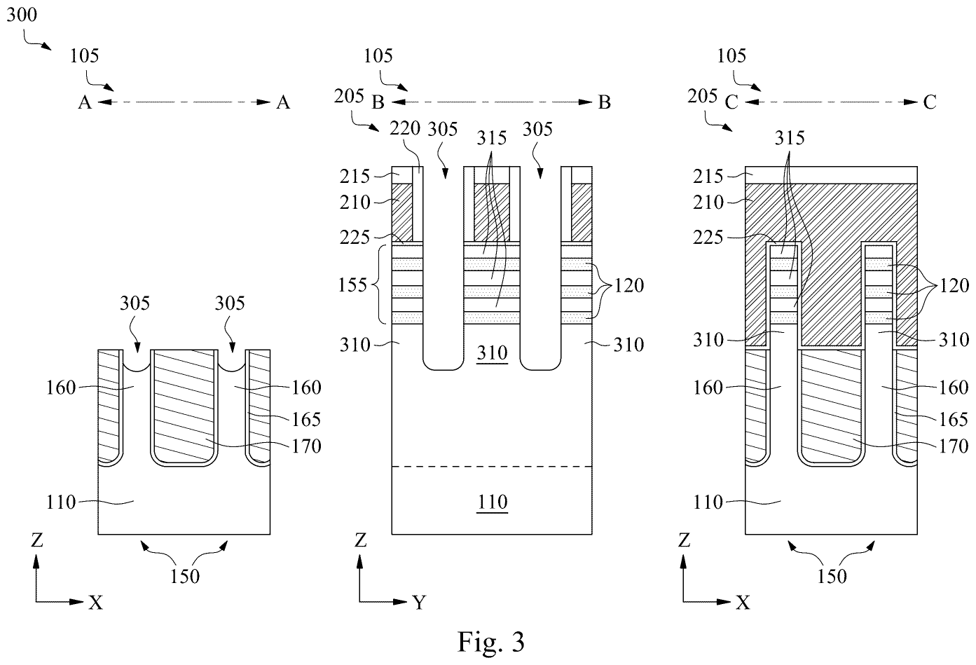

FIG. 3 is a diagrams of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through portions 155 of a fin structure 150 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 160 of the fin structure 150. This results in formation of mesa regions 310 in the fin structure 150. The sidewalls of the portions of each source/drain recess 305 below the portions 155 correspond to sidewalls of mesa regions 310. A mesa region 310 (also referred to as pedestals) refers to a region of the fin portion 160 of the fin structure 150 on which nanostructure channels are defined from the nanostructure channel layers 125. The nanostructure channels 315 extend between adjacent source/drain recesses 305 and are located under the dummy gate structure 205 between the adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As indicated above, FIG. 3 is provided as an example. Other examples may differ from what is described with regard to FIG. 3.

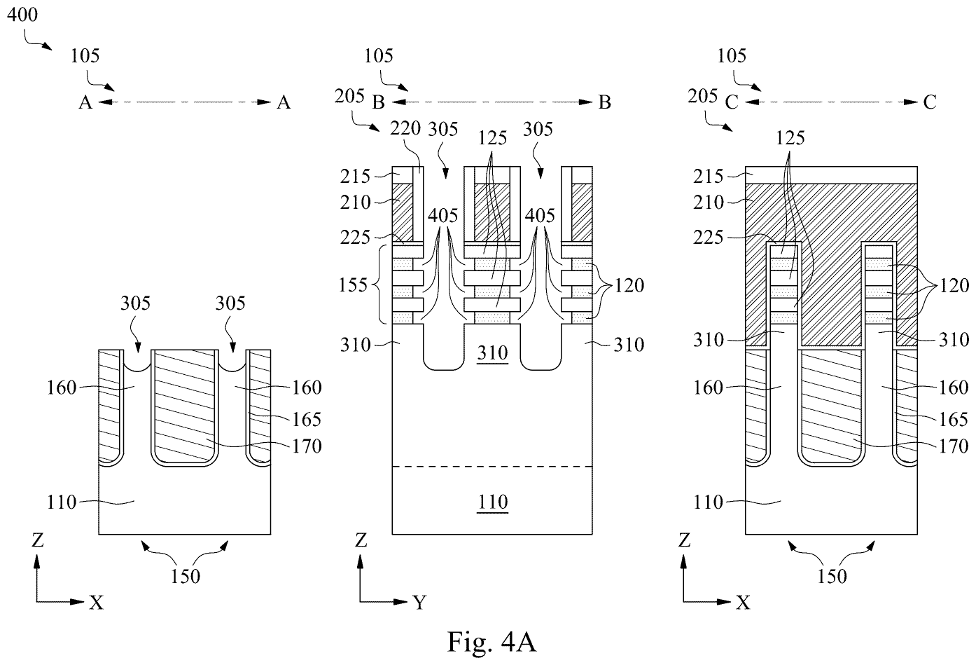

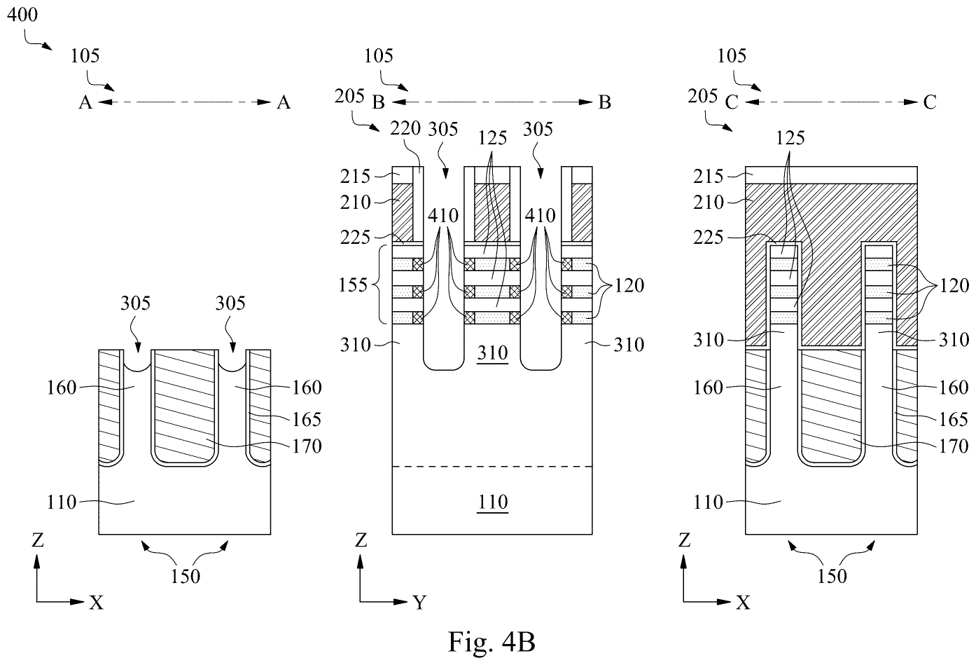

FIGS. 4A and 4B are diagrams of an example implementation 400 of an inner spacer formation process described herein. The example implementation 400 includes an example of forming inner spacers between ends of the nanostructure channels 315 that are exposed in the source/drain recesses 305. FIGS. 4A and 4B are each illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 400 are performed after the processes described in connection with FIGS. 1A-3.

As shown in the cross-sectional plane B-B in FIG. 4A, the ends of the sacrificial nanostructure layers 120 that are exposed in the source/drain recesses 305 are laterally etched (e.g., in the x-direction that is approximately parallel to a length of the sacrificial nanostructure layers 120) in an etch operation, thereby forming cavities 405 between the ends of the nanostructure channels 315 that are exposed in the source/drain recesses 305. In particular, an etch tool may be use to laterally etch the ends of the sacrificial nanostructure layers 120 under the dummy gate structures 205 through the source/drain recesses 305 to form the cavities 405 between ends of the nanostructure channels 315. The cavities 405 may be formed to an approximately curved shape, an approximately concave shape, an approximately triangular shape, an approximately square shape, or to another shape.

As shown in the cross-sectional plane A-A and in the cross-sectional plane B-B in FIG. 4B, inner spacers (InSP) 410 are formed in the cavities 405 between the ends of vertically adjacent nanostructure channels 315 in the source/drain recesses 305. The inner spacer 410 are included to reduce parasitic capacitance in the nanostructure transistors and to protect source/drain regions (that are subsequently formed in the source/drain recesses 305) from being etched in a nanosheet release operation to remove the sacrificial nanostructure layers 120 between the nanostructure channels 315. The inner spacers 410 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

To form the inner spacers 410, a deposition tool may be used to deposit a layer of dielectric material in the cavities 405 and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 410 in the cavities 405. In some implementations, the etch operation may result in the surfaces of the inner spacers 410 facing the source/drain recesses 305 being curved or recessed. In some implementations, the surfaces of the inner spacers 410 facing the source/drain recesses 305 are approximately flat such that the surfaces of the inner spacers 410 and the surfaces of the ends of the nanostructure channels 315 are approximately even and flush.

As indicated above, FIGS. 4A and 4B are provided as an example. Other examples may differ from what is described with regard to FIGS. 4A and 4B.

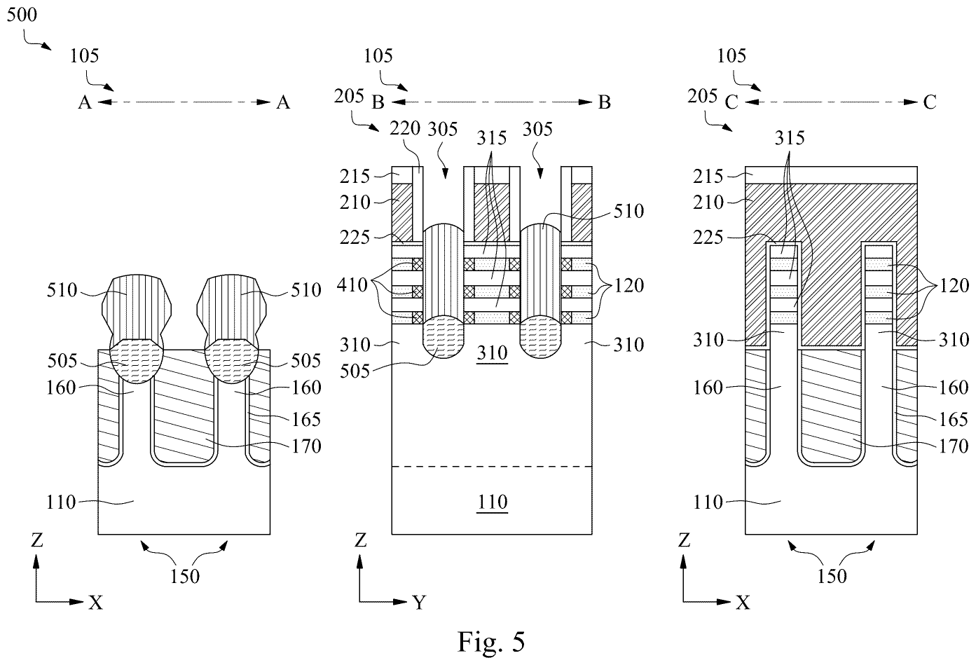

FIG. 5 is a diagram of an example implementation 500 of a source/drain region formation process described herein. The example implementation 500 includes an example of forming the source/drain regions of the nanostructure transistors of the semiconductor device 105. FIG. 5 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 500 are performed after the processes described in connection with FIGS. 1A-4B.

As shown in the cross-sectional plane A-A and the cross-sectional plane B-B in FIG. 5, the source/drain recesses 305 are filled with one or more layers to form the source/drain regions in the source/drain recesses 305. For example, a deposition tool may be used to deposit a buffer region 505 at the bottom of a he source/drain recess 305, and a deposition tool may deposit a source/drain region 510 on the buffer region 505 in the source/drain recess 305. In some implementations, a deposition tool is used to deposit a capping layer on the source/drain regions 510 in the source/drain recess 305.

A buffer region 505 may include silicon (Si), silicon doped with boron (SiB) or another dopant, and/or another material. A buffer region 505 may be included between a source/drain region 510 and the mesa regions 310 adjacent to the buffer region 505 to reduce, minimize, and/or prevent dopant migration and/or current leakage from the source/drain region 510 into the adjacent mesa region 310, which might otherwise cause short channel effects in the semiconductor device 105. Accordingly, the buffer region 505 may increase the performance of the semiconductor device 105 and/or increase yield of the semiconductor device 105.

A source/drain region 510 may refer to a source or a drain, individually or collectively dependent upon the context. Source/drain regions 510 may be included on opposing sides of a dummy gate structure 205 such that the nanostructure channels 315 under the dummy gate structure 205 extend between, and are electrically coupled with, source/drain regions 510. The source/drain regions 510 each include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 105 may include p-type metal-oxide semiconductor (PMOS) nanostructure transistors that include p-type source/drain regions 510, n-type metal-oxide semiconductor (NMOS) nanostructure transistors that include n-type source/drain regions 510, and/or other types of nanostructure transistors.

One or more layers of a source/drain region 510 may be epitaxially grown, deposited (e.g., using CVD, PVD, ALD), and/or may be formed using one or more other deposition techniques. For example, a deposition tool may epitaxially grow a first layer of a source/drain region 510 (referred to as an L1) over an associated buffer region 505 (which may be referred to as an L0), and may epitaxially grow a second layer of the source/drain region 510 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 105 and to reduce dopant extrusion or migration into the nanostructure channels 315. The second layer may include a highly doped silicon or highly doped silicon germanium. The second layer may be included to provide a compressive stress in the source/drain regions 510 to reduce boron loss.

As indicated above, FIG. 5 is provided as an example. Other examples may differ from what is described with regard to FIG. 5.

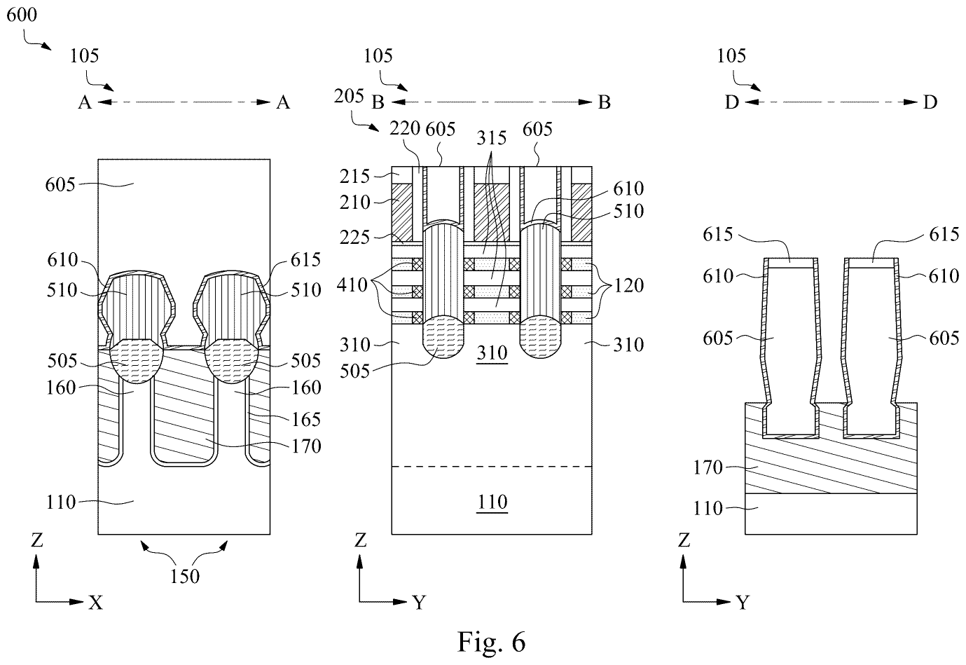

FIG. 6 is a diagram of an example implementation 600 of an interlayer dielectric (ILD) formation process described herein. FIG. 6 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane D-D in FIG. 2. In some implementations, the operations described in connection with the example implementation 600 are performed after the processes described in connection with FIGS. 1A-5.

As shown in the cross-sectional plane A-A and in the cross-sectional plane B-B in FIG. 6, a dielectric layer 605 is formed over the source/drain regions 510. The dielectric layer 605 (which may be referred to as an ILD layer) fills in areas between the dummy gate structures 205. The dielectric layer 605 is formed to reduce the likelihood of and/or prevent damage to the source/drain regions 510 during a replacement gate process to replace the dummy gate structures 205. The dielectric layer 605 may be referred to as an ILD zero (ILDO) layer or another ILD layer.

As shown in the cross-sectional plane A-A, in the cross-sectional plane B-B in FIG. 6, and in the cross-sectional plane D-D in FIG. 6, a contact etch stop layer (CESL) 610 is conformally deposited (e.g., by a deposition tool) over the source/drain regions 510 prior to formation of the dielectric layer 605. The CESL 610 may provide a mechanism to stop an etch process when forming contacts or vias for the source/drain regions 510. The CESL 610 may be formed of a dielectric material having a different etch selectivity from adjacent layers or components. The CESL 610 may include or may be a nitrogen containing material, a silicon containing material, and/or a carbon containing material. Furthermore, the CESL 610 may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL 610 may be deposited using a deposition process, such as ALD, CVD, or another deposition technique. In some implementations, a capping layer 615 is formed on the dielectric layer 605.

As indicated above, FIG. 6 is provided as an example. Other examples may differ from what is described with regard to FIG. 6.

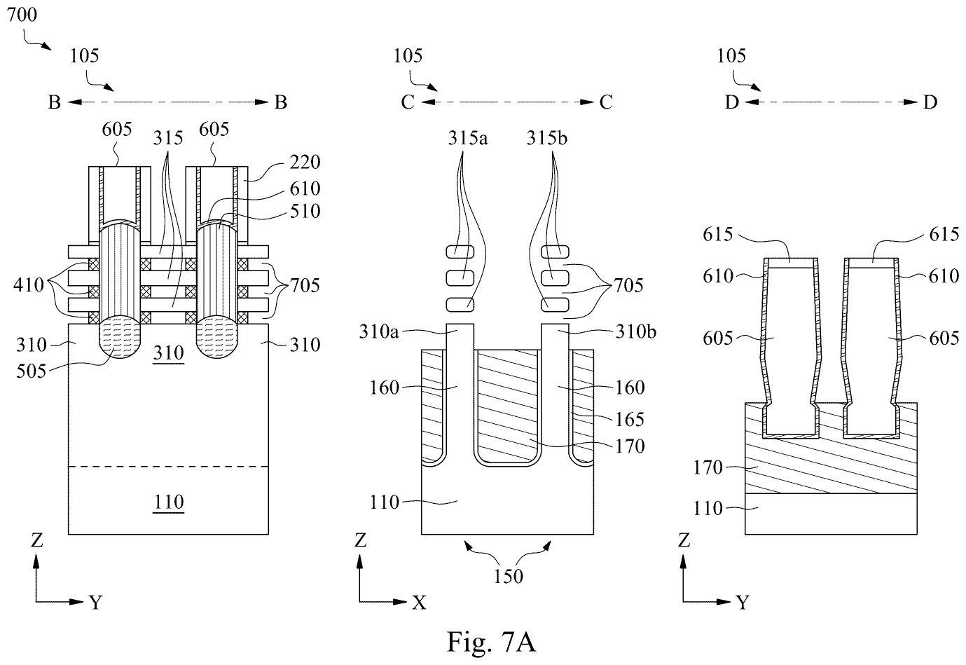

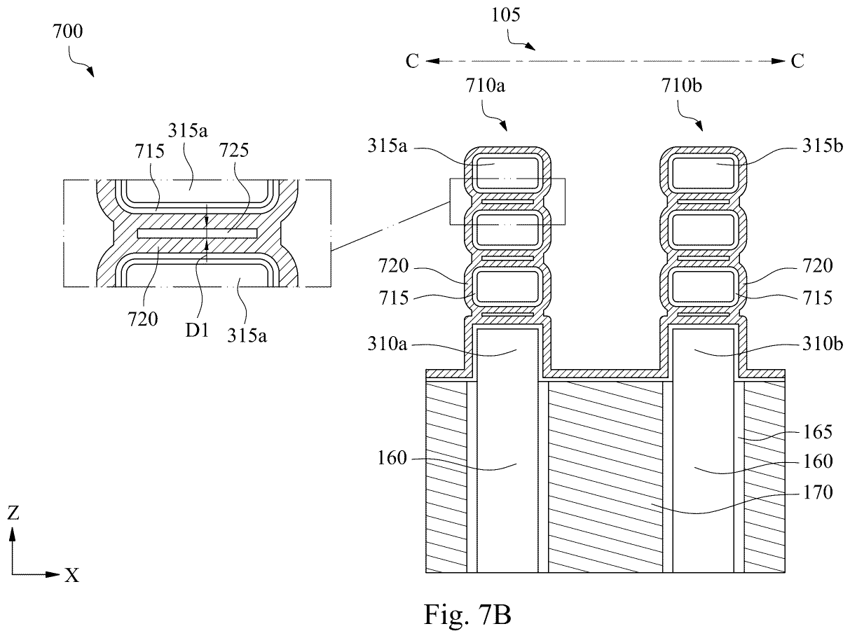

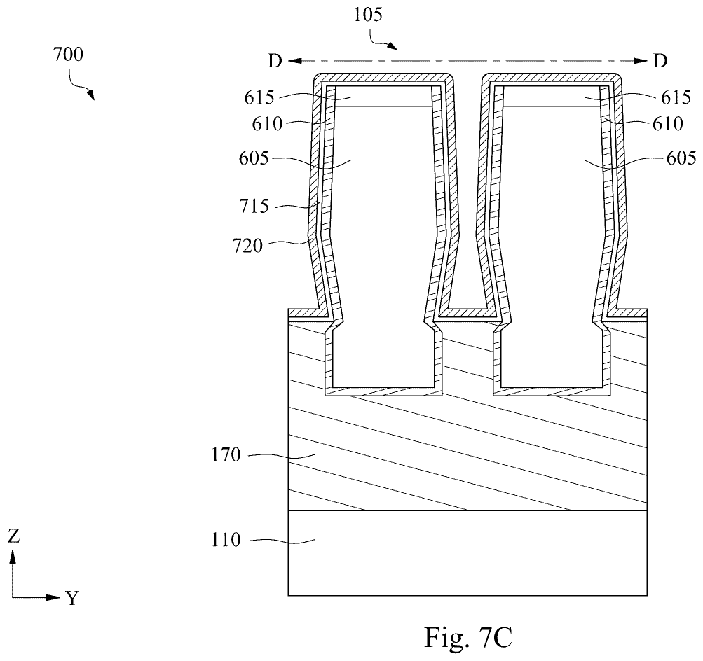

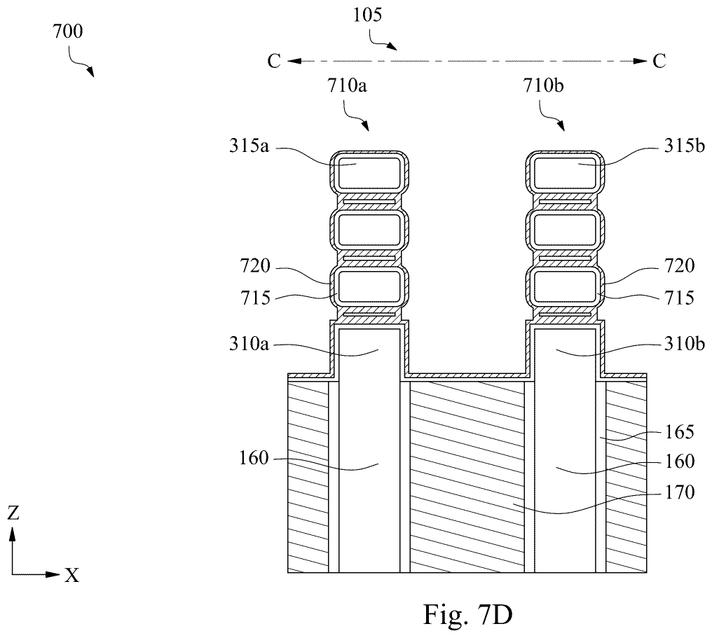

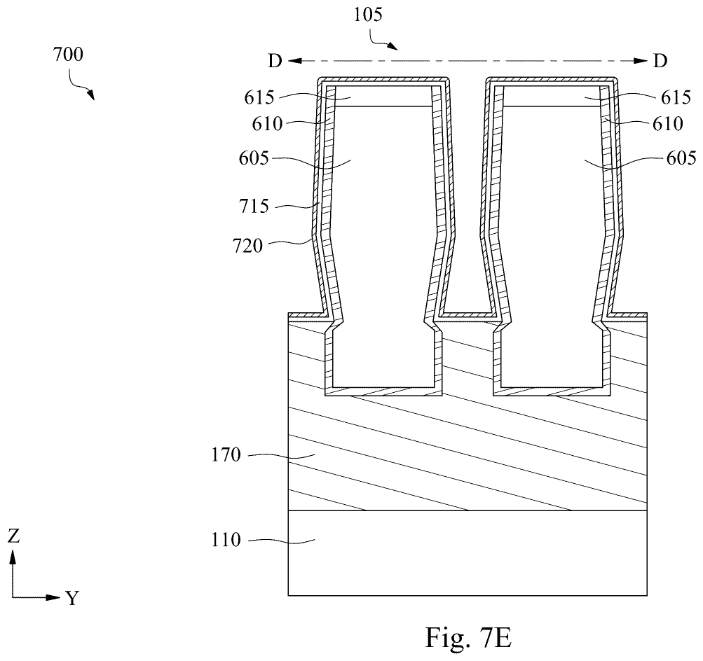

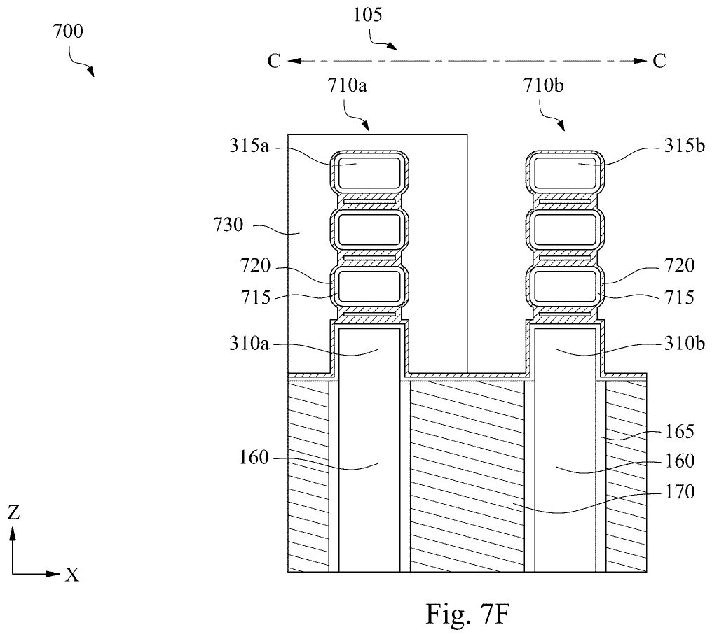

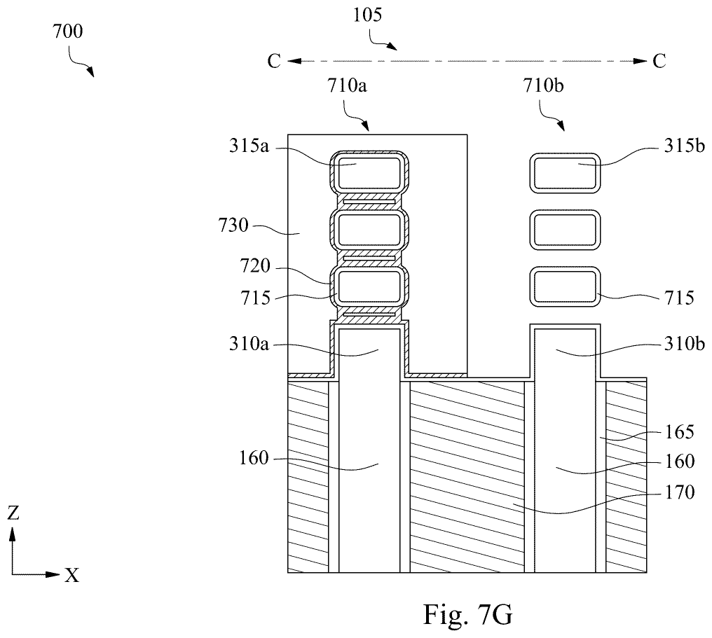

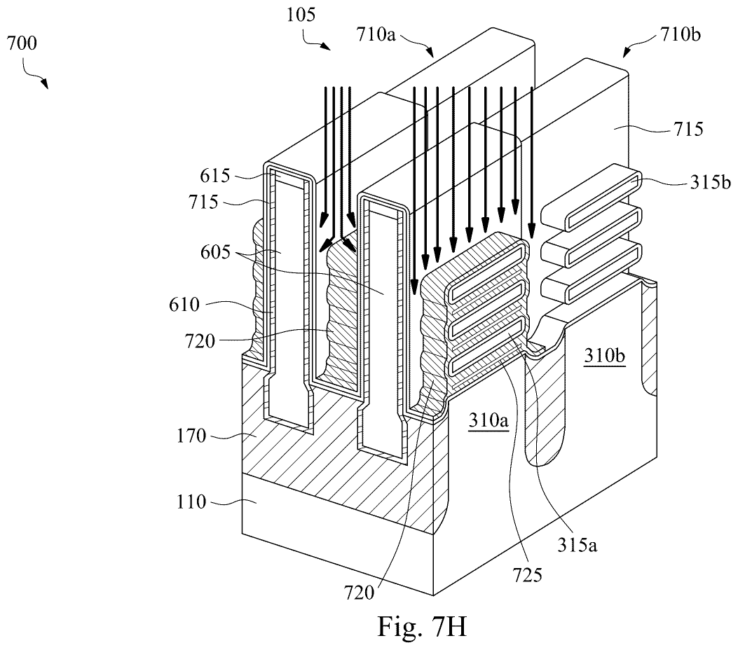

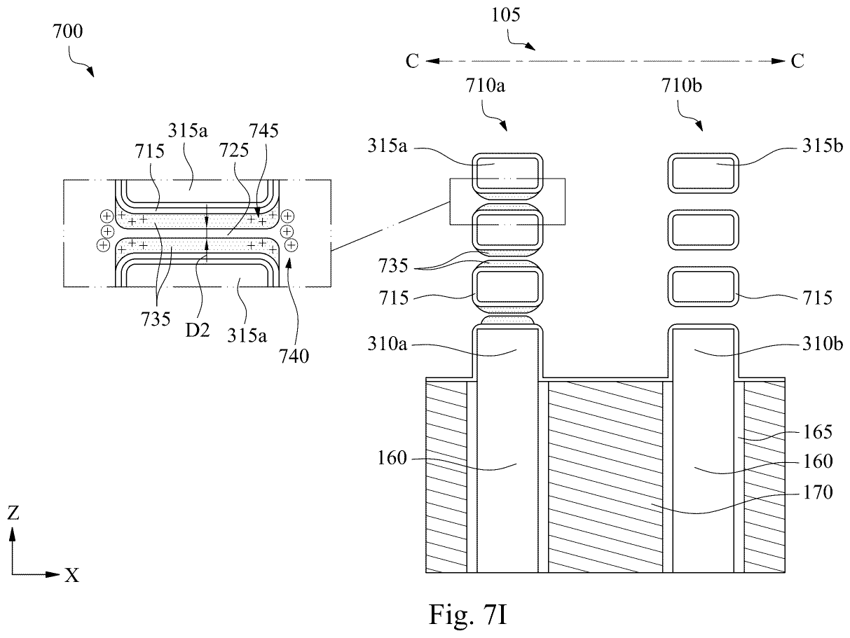

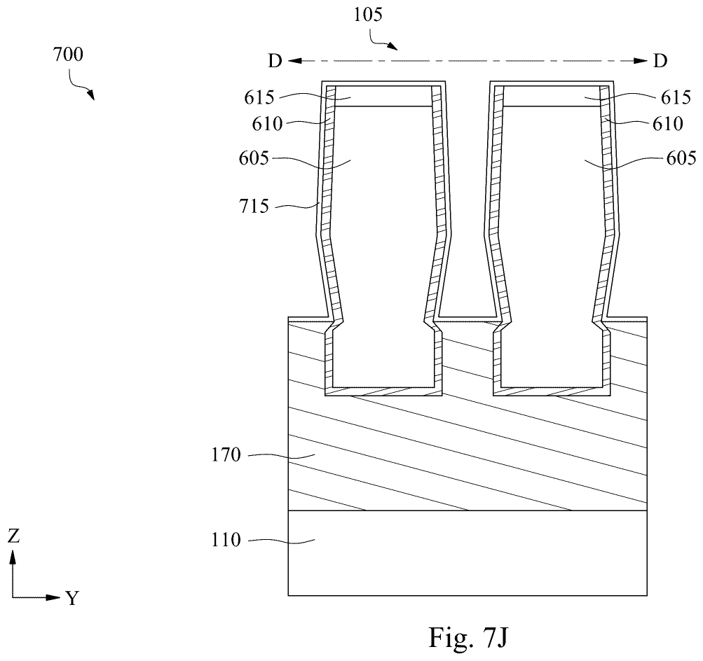

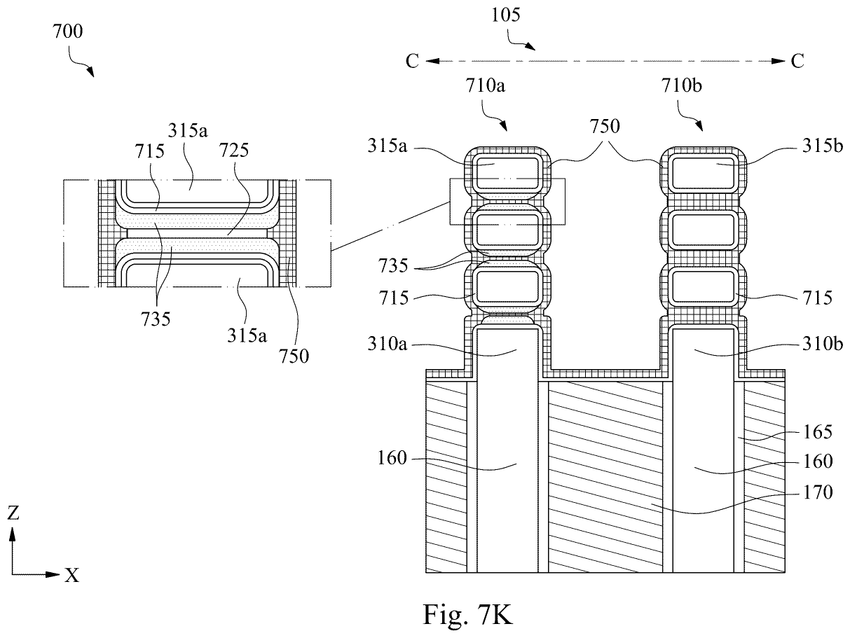

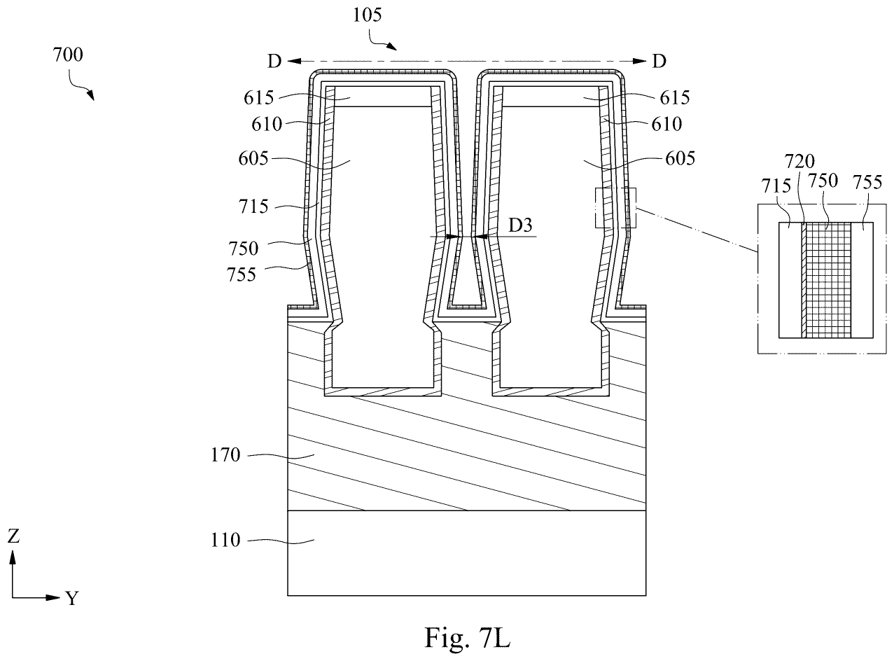

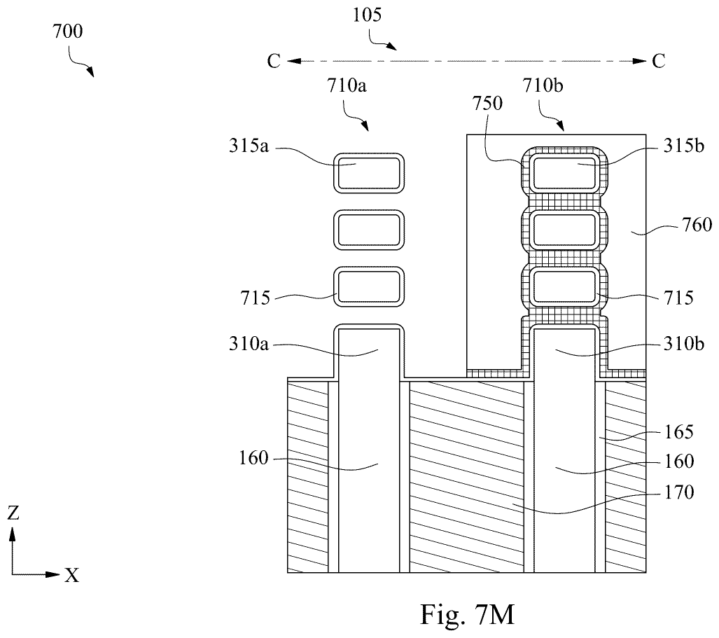

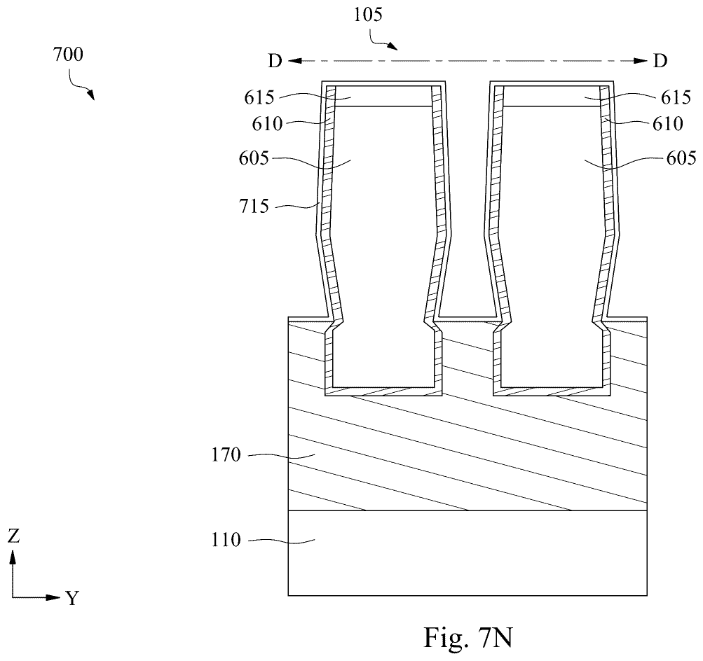

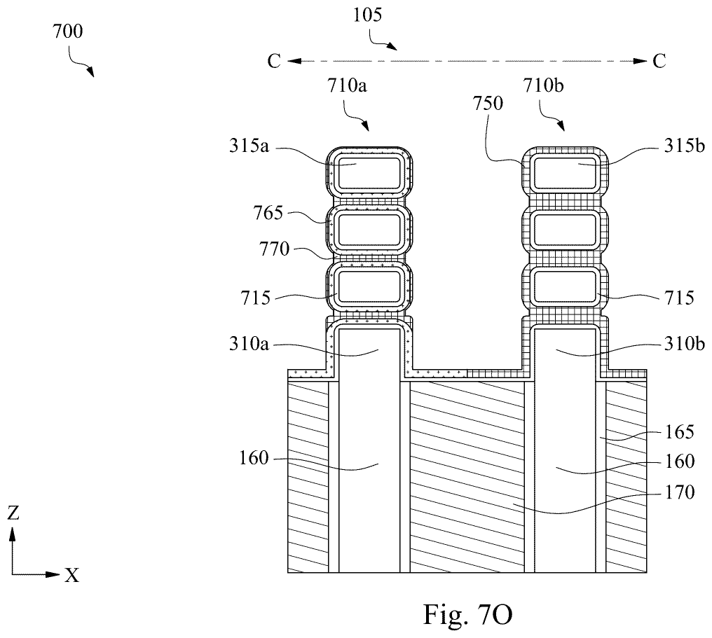

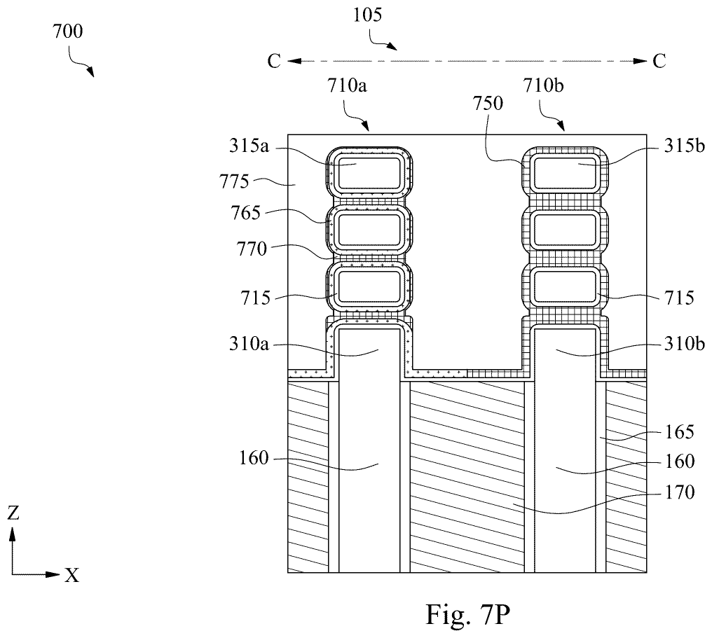

FIGS. 7A-7P are diagrams of an example implementation 700 of a replacement gate (RPG) process described herein. The example implementation 700 includes an example of a replacement gate process for replacing the dummy gate structures 205 with high-k/metal gate structures (e.g., the replacement gate structures) for the nanostructure transistors of the semiconductor device 105. FIGS. 7A-7P are each illustrated from a plurality of perspectives illustrated in FIG. 2, including the perspective of the cross-sectional plane A-A in FIG. 2, the perspective of the cross-sectional plane B-B in FIG. 2, the perspective of the cross-sectional plane C-C in FIG. 2, and/or the perspective of the cross-sectional plane D-D in FIG. 2. In some implementations, the operations described in connection with the example implementation 700 are performed after the operations described in connection with FIGS. 1A-6.

As shown in the cross-sectional plane B-B and the cross-sectional plane C-C in FIG. 7A, the replacement gate process includes a dummy gate removal operation. The dummy gate removal operation includes removing the dummy gate structures 205 from the semiconductor device 105. The removal of the dummy gate structures 205 leaves behind openings (or recesses) between the dielectric layer 605, and provides access to the underlying sacrificial nanostructure layers 120. The dummy gate structures 205 may be removed in one or more etch operations. Such etch operations may include a plasma etch technique, a wet chemical etch technique, and/or another type of etch technique.

The removal of the dummy gate structures 205 exposes a mesa region 310a and a stack of nanostructure channels 315a that are arranged above the mesa region 310a in the z-direction in the semiconductor device 105. The removal of the dummy gate structures 205 also exposes a mesa region 310b and a stack of nanostructure channels 315b that are arranged above the mesa region 310b in the z-direction in the semiconductor device 105. The nanostructure channels 315a and the nanostructure channels 315b extend in the y-direction in the semiconductor device 105. Nanostructure channels 315a and the nanostructure channels 315b may be arranged in the x-direction in the semiconductor device 105 such that the nanostructure channels 315a and the nanostructure channels 315b are side-by-side or laterally adjacent in the semiconductor device 105.

The mesa region 310a and the nanostructure channels 315a may be exposed in preparation for forming an n-type gate structure, of an NMOS nanostructure transistor of the semiconductor device 105, around the nanostructure channels 315a. The mesa region 310b and the nanostructure channels 315b may be exposed in preparation for forming a p-type gate structure, of a PMOS nanostructure transistor of the semiconductor device 105, around the nanostructure channels 315b.

As further shown FIG. 7A, the replacement gate process includes a nanostructure release operation (e.g., an SiGe release operation). The nanostructure release operation is performed to remove the sacrificial nanostructure layers 120 (e.g., the silicon germanium layers). This results in openings 705 between the nanostructure channels 315a (e.g., the areas around the nanostructure channels 315a) and openings 705 between the nanostructure channels 315b (e.g., the areas around the nanostructure channels 315b). The sacrificial nanostructure layers 120 may be removed through the spaces that were previously occupied by the dummy gate structures 205. The nanostructure release operation may include the use of an etch tool to perform an etch operation to remove the sacrificial nanostructure layers 120 based on a difference in etch selectivity between the material of the sacrificial nanostructure layers 120 and the material of the nanostructure channels 315a and 315b, and between the material of the sacrificial nanostructure layers 120 and the material of the inner spacers 410. The inner spacers 410 may function as etch stop layers in the etch operation to protect the source/drain regions 510 from being etched.

As shown in the cross-sectional plane C-C and/or in the cross-sectional plane D-D in FIGS. 7B-7P, the replacement gate operation continues where gate structures (e.g., replacement gate structures) are formed in the openings 705 between the nanostructure channels 315a and 315b for the nanostructure transistors of the semiconductor device 105. In particular, an n-type gate structure 710a is formed in the areas between and around the nanostructure channels 315a for an NMOS nanostructure transistor of the semiconductor device 105. The n-type gate structure 710a occupies the areas that were previously occupied by the sacrificial nanostructure layers 120 such that the n-type gate structure 710a wraps around the nanostructure channels 315a and surrounds the nanostructure channels 315a on at least three sides of the nanostructure channels 315a. In some implementations, the n-type gate structure 710a fully wraps around the nanostructure channels 315a and surrounds the nanostructure channels 315a on all four sides of the nanostructure channels 315a.

A p-type gate structure 710b is formed in the areas between and around the nanostructure channels 315b for a PMOS nanostructure transistor of the semiconductor device 105. The p-type gate structure 710b occupies the areas that were previously occupied by the sacrificial nanostructure layers 120 such that the p-type gate structure 710b wraps around the nanostructure channels 315b and surrounds the nanostructure channels 315b on at least three sides of the nanostructure channels 315b. In some implementations, the p-type gate structure 710b fully wraps around the nanostructure channels 315b and surrounds the nanostructure channels 315b on all four sides of the nanostructure channels 315b.

As shown in FIG. 7B, a gate dielectric layer 715 may be formed around the nanostructure channels 315a and 315b, and on the mesa regions 310a and 310b. A deposition tool may be used to deposit the gate dielectric layer 715 using a PVD technique, an ALD technique, a CVD technique, an oxidation technique, and/or another suitable deposition technique. In some implementations, the gate dielectric layer 715 is a high-k gate dielectric layer that includes one or more high-k materials (e.g., dielectric materials having a dielectric constant greater than silicon dioxide (SiO₂-dielectric constant of approximately 3.9). Examples include lanthanum oxide (LaₓO_{y} such as La₂O₃), hafnium oxide (HfOₓ such as HfO₂), zirconium oxide (ZrOₓ such as ZrO₂), and/or aluminum oxide (AlₓO_{y} such as Al₂O₃), among other examples. Additionally and/or alternatively, silicon dioxide (SiO₂) and/or another dielectric material may be used instead of a high-k dielectric material. In some implementations, the gate dielectric layer 715 may have a thickness that is included in a range of approximately 0.5 nanometers to approximately 3 nanometers. However, other values for the range are within the scope of the present disclosure.

As further shown in FIG. 7B, a sacrificial spacer layer 720 is formed on the gate dielectric layer 715 such that the sacrificial spacer layer 720 wraps around the nanostructure channels 315a and 315b. The sacrificial spacer layer 720 is also formed on the mesa regions 310a and 310b. A deposition tool may be used to deposit the gate dielectric layer 715 using a PVD technique, an ALD technique, a CVD technique, an oxidation technique, and/or another suitable deposition technique. The sacrificial spacer layer 720 includes one or more materials that can be selectively etched relative to the gate dielectric layer 715, which enables the sacrificial spacer layer 720 to be subsequently removed with minimal to no etching of the gate dielectric layer 715. Examples of materials for the sacrificial spacer layer 720 include aluminum oxide (AlₓO_{y} such as Al₂O₃), titanium nitride (TiN), and/or tungsten carbonitride (WCN), among other examples.

The sacrificial spacer layer 720 may be formed to a thickness such that the sacrificial spacer layer 720 at least partially merges between vertically adjacent nanostructure channels 315a (e.g., adjacent in the z-direction) and between vertically adjacent nanostructure channels 315b. In some implementations, the sacrificial spacer layer 720 is formed to a thickness that is included in a range of approximately 30 angstroms to approximately 35 angstroms. However, other values and/or ranges for the thickness of the sacrificial spacer layer 720 are within the scope of the present disclosure. Seams (or voids) 725 form in the sacrificial spacer layer 720 between vertically adjacent nanostructure channels 315a and/or between vertically adjacent nanostructure channels 315b. The seams 725 may have a z-direction width (indicated in FIG. 7B as dimension D1) that is less than approximately 1 nanometer.

As shown in FIG. 7C, the sacrificial spacer layer 720 may be conformally deposited on regions of the dielectric layer 605. The sacrificial spacer layer 720 may conform to the cross-sectional profile of the regions of the dielectric layer 605.

As shown in FIGS. 7D and 7E, an etch-back operation may be performed to thin the sacrificial spacer layer 720 (e.g., to reduce the thickness of the sacrificial spacer layer 720. For example, the thickness of the sacrificial spacer layer 720 prior to the etch-back operation may be included in a range of approximately 30 angstroms to approximately 35 angstroms, and the thickness of the sacrificial spacer layer 720 after the etch-back operation may be included in a range of approximately 15 angstroms to approximately 20 angstroms. However, other values and/or ranges for the thickness of the sacrificial spacer layer 720 are within the scope of the present disclosure.

An etch tool may be used to etch the sacrificial spacer layer 720 in the etch-back operation. A dry etch technique (e.g., a plasma-based etch technique, a gas-based etch technique), a wet etch technique (e.g., a wet chemical etch technique), and/or another suitable etch technique may be used to etch the sacrificial spacer layer 720 to reduce the thickness of the sacrificial spacer layer 720.

As shown in FIGS. 7F and 7G, a masking layer 730 may be used to remove the sacrificial spacer layer 720 from the nanostructure channels 315b and from the mesa region 310b. The masking layer 730 protects the sacrificial spacer layer 720 on the nanostructure channels 315a and on the mesa region 310a such that the sacrificial spacer layer 720 remains on the nanostructure channels 315a and on the mesa region 310a.

A deposition tool may be used to deposit the masking layer 730 on the nanostructure channels 315a and 315b and on the mesa regions 310a and 310b. The masking layer 730 may then be patterned by removing a portion of the masking layer 730 from the nanostructure channels 315b and from the mesa region 310b. An etch tool may be used to etch the masking layer 730 to pattern the masking layer 730.

An etch tool may then be used to remove the sacrificial spacer layer 720 from the nanostructure channels 315b and from the mesa region 310b while the masking layer 730 protects the nanostructure channels 315a and the mesa region 310a. In some implementations, a wet etch technique is used to remove the sacrificial spacer layer 720 from the nanostructure channels 315b and from the mesa region 310b. For example, a basic (or alkaline) wet etchant (e.g., a wet etchant having a pH that is greater than 7), such as ammonium hydroxide (NH₄OH), may be used to isotropically etch the sacrificial spacer layer 720 to remove the sacrificial spacer layer 720 from the nanostructure channels 315b and from the mesa region 310b with minimal to no etching of the gate dielectric layer 715 on the nanostructure channels 315b and on the mesa region 310b. The ammonium hydroxide wet etchant includes negatively charged ions (e.g., OH ions) that enable the sacrificial spacer layer 720 to be isotropically etched because the material of the sacrificial spacer layer 720 (e.g., aluminum oxide (Al₂O₃), among other examples) may have a positive surface charge that attracts the negatively charged ions in the ammonium hydroxide wet etchant.

The masking layer 730 may be subsequently removed from the nanostructure channels 315a and from the mesa region 310a using a plasma ashing technique (e.g., using a nitrogen (N₂) plasma and a hydrogen (H₂) reactant gas) and/or another type of masking layer removal technique.

As shown in FIGS. 7H-7J, another etch-back operation may be performed to trim the sacrificial spacer layer 720 that is on the nanostructure channels 315a and on the mesa region 310a. The sacrificial spacer layer 720 is also removed from the sidewalls of the regions of the dielectric layer 605 and from the top surfaces of the dielectric layer 605 and the STI regions 170.

As shown in FIG. 7I, the portions of the sacrificial spacer layer 720 on the sidewalls of the nanostructure channels 315a and on the sidewalls of the mesa region 310a may be anisotropically etched such that the portions of the sacrificial spacer layer 720 on the sidewalls of the nanostructure channels 315a and on the sidewalls of the mesa region 310a are removed. As a result, portions of the sacrificial spacer layer 720 between vertically adjacent nanostructure channels 315a remain as sacrificial spacers 735. The portions of the sacrificial spacer layer 720 on the STI regions 170 and on the top surface of the top-most nanostructure channel 315a are also removed in the etch-back operation.

The anisotropic etch of the sacrificial spacer layer 720 may be achieved through the use of an acidic wet etchant (e.g., a wet etchant having a pH that is less than 7) that includes positive ions 740. Thus, a wet etchant that is different from the wet etchant that was used to remove the sacrificial spacer layer 720 from the nanostructure channels 315b and from the mesa region 310b may be used to trim the sacrificial spacer layer 720 on the nanostructure channels 315a and on the mesa region 310a. For example, a wet etchant that includes hydrogen (H⁺) ions may be used to trim the sacrificial spacer layer 720 on the nanostructure channels 315a and on the mesa region 310a. The use of an amphoteric material, such as aluminum oxide, for the sacrificial spacer layer 720 enables the sacrificial spacer layer 720 to be etched by basic wet etchants as well as acidic wet etchants. Examples of acidic wet etchants include hydrochloric acid (HCl), sulfuric acid (H₂SO₄), hydrobromic acid (HBr), and/or carbon dioxide (CO₂) dissolved in water (H₂O), among other examples. In some implementations, the wet etchant is diluted in water to a concentration that is included in a range of approximately 0.1 parts per million (ppm) to approximately 1×10⁷ ppm. However, other values and/or ranges are within the scope of the present disclosure. An example reaction between the wet etchant and the material of the sacrificial spacer layer 720 may include:

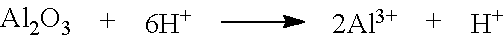

where the hydrogen ions break down the aluminum oxide into aluminum cations and byproducts such as water (H₂O). The hydrogen ions may protonate the oxygen atoms in the aluminum oxide, leading to breakdown of the solid aluminum oxide into soluble aluminum cations and water molecules.

The material of the sacrificial spacer layer 720 may have a positive surface charge 745. The positive surface charge 745 of the sacrificial spacer layer 720 repels the positive ions 740 in the wet etchant. The charge repulsion between the positive surface charge 745 of the sacrificial spacer layer 720 and the positive ions 740 in the wet etchant promotes vertical etching (e.g., z-direction etching) of the sacrificial spacer layer 720 and inhibits or resists lateral etching (e.g., x-direction etching, y-direction etching) of the sacrificial spacer layer 720. In particular, the positive surface charge 745 of the sacrificial spacer layer 720 repels the positive ions 740 in the wet etchant from entering the seams 725 in the sacrificial spacer layer 720 between vertically adjacent nanostructure channels 315a. This prevents or minimizes etching of the sacrificial spacer layer 720 between vertically adjacent nanostructure channels 315a, which enables minimal to no widening of the seams 725 between sacrificial spacers 735. Accordingly, the z-direction width of the seams 725 after the etch-back operation (indicated in FIG. 7I as dimension D2) may also be less than approximately 1 nanometer.

As further shown in FIG. 71, the wet etchant that is used to trim the sacrificial spacer layer 720 to form the sacrificial spacers 735 may also etch the gate dielectric layer 715 on the nanostructure channels 315a and/or on the nanostructure channels 315b. This may result in an amount of corner rounding of the gate dielectric layer 715 at the corners of the nanostructure channels 315a and/or at the corners of the nanostructure channels 315b in the x-direction. Thus, an angle between the gate dielectric layer 715 on a sidewall of a nanostructure channel 315a and the gate dielectric layer 715 on a top or bottom surface of the nanostructure channel 315a in the x-direction, after the etch-back operation described in connection with FIGS. 7H-7J, may be greater than the angle between the gate dielectric layer 715 on the sidewall of the nanostructure channel 315a and the gate dielectric layer 715 on the top or bottom surface of the nanostructure channel 315a prior to the etch-back operation described in connection with FIGS. 7H-7J. Additionally and/or alternatively, an angle between a gate dielectric layer 715 on a sidewall of a nanostructure channel 315b and the gate dielectric layer 715 on a top or bottom surface of the nanostructure channel 315b in the x-direction, after the etch-back operation described in connection with FIGS. 7H-7J, may be greater than the angle between the gate dielectric layer 715 on the sidewall of the nanostructure channel 315b and the gate dielectric layer 715 on the top or bottom surface of the nanostructure channel 315b prior to the etch-back operation described in connection with FIGS. 7H-7J. For example, an angle between a gate dielectric layer 715 on a sidewall of a nanostructure channel 315a (or 315b) and the gate dielectric layer 715 on a top or bottom surface of the nanostructure channel 315a (or 315b) in the x-direction prior to the etch-back operation described in connection with FIGS. 7H-7J may be less than approximately 100 degrees, and the angle between the gate dielectric layer 715 on the sidewall of the nanostructure channel 315a (or 315b) and the gate dielectric layer 715 on the top or bottom surface of the nanostructure channel 315a (or 315b) in the x-direction after the etch-back operation described in connection with FIGS. 7H-7J may be greater than or approximately equal to 100 degrees. However, other values for the range are within the scope of the present disclosure.

As shown in FIG. 7J, the sacrificial spacer layer 720 is removed (e.g., fully removed) from the sidewalls of the regions of the dielectric layer 605 with minimal to no residual material of the sacrificial spacer layer 720 remaining on the sidewalls of the regions of the dielectric layer 605.

As shown in FIGS. 7K and 7L, a p-type work function metal layer 750 is formed on the gate dielectric layer 715 such that the p-type work function metal layer 750 wraps around the nanostructure channels 315a and 315b. The p-type work function metal layer 750 may also be formed on the mesa regions 310a and 310b. In some implementations, the p-type work function metal layer 750 wrapping around the nanostructure channels 315b is merged between the nanostructure channels 315b. In some embodiments, the p-type work function metal layer 750 wrapping around the nanostructure channels 315b is not merged between the nanostructure channels 315b.

Since the p-type gate structure 710b is a metal gate structure, the p-type work function metal layer 750 may be included in the p-type gate structure 710b for work function tuning of the p-type gate structure 710b. The p-type work function metal layer 750 may include one or more p-type metals, such as tungsten (W), cobalt (Co), titanium nitride (TiN), tungsten nitride (WN), and/or another metal having a work function that is greater than approximately 4.7 eV, among other examples. The p-type work function metal layer 750 may be included to tune the work function of the PMOS nanostructure transistor such that the work function is adjusted close to the valance band of the material of the nanostructure channels 315b. This enables a relatively low threshold voltage to be achieved for the PMOS nanostructure transistor while enabling a relatively low current leakage to be achieved for the PMOS nanostructure transistor.

A deposition tool may be used to deposit the p-type work function metal layer 750 using a PVD technique, an ALD technique, a CVD technique, an oxidation technique, another type of deposition technique described in connection with FIG. 1, and/or another suitable deposition technique. The p-type work function metal layer 750 may be deposited in one or more deposition operations. In some implementations, the p-type work function metal layer 750 is formed to a thickness that is included in a range of approximately 0.5 nanometers to approximately 20 nanometers. However, other values for the range are within the scope of the present disclosure.

The p-type work function metal layer 750 is also formed on the nanostructure channels 315a and on the sidewalls of the mesa region 310a due to the p-type work function metal layer 750 being formed without the use of a masking layer on the nanostructure channels 315a and on the mesa region 310a. As shown in FIG. 7K, the sacrificial spacers 735 prevent or minimize the deposition of material of the p-type work function metal layer 750 in between vertically adjacent nanostructure channels 315a, and between the bottom-most nanostructure channel 315a and the mesa region 310a. In particular, the anisotropic etch described above in connection with FIGS. 7H-7J for trimming the sacrificial spacer layer 720 to form the sacrificial spacers 735 inhibits the widening of the seams 725 between the sacrificial spacers 735. Thus, the seams 725 are too small to facilitate the deposition of the material of the p-type work function metal layer 750 into the seams 725.

As shown in FIG. 7L, the p-type work function metal layer 750 may also be formed on the sidewalls of the regions of the dielectric layer 605. In some implementations, an additional p-type work function metal layer 755 may also be formed on the p-type work function metal layer 750. The p-type work function metal layer 755 may include tantalum nitride (TaN) and/or another type of p-type work function metal.

The anisotropic etch described above in connection with FIGS. 7H-7J for trimming the sacrificial spacer layer 720 to form the sacrificial spacers 735 enables the sacrificial spacer layer 720 to be fully removed from the sidewalls of the regions of the dielectric layer 605 with minimal to no residual material of the sacrificial spacer layer 720 remaining on the sidewalls of the regions of the dielectric layer 605. Accordingly, and as shown in FIG. 7L, the p-type work function metal layer 750 formed on the sidewalls of adjacent regions of the dielectric layer 605 is not merged in the y-direction between the adjacent regions of the dielectric layer 605. Instead, the p-type work function metal layer 750 formed on the sidewalls of adjacent regions of the dielectric layer 605 is physically separated by a distance (indicated in FIG. 7L as dimension D3) in the y-direction between the adjacent regions of the dielectric layer 605. This prevents, minimizes, and/or reduces the likelihood of a masking layer that is used to remove the p-type work function metal layer 750 from the n-type gate structure 710a from becoming trapped between the adjacent regions of the dielectric layer 605, which might otherwise result in under etching of the masking layer and residual material of the masking layer remaining between the adjacent regions of the dielectric layer 605.

As shown in FIG. 7M, the p-type work function metal layer 750 may be removed from the nanostructure channels 315a and from the mesa region 310a. If the p-type work function metal layer 750 were to remain around the nanostructure channels 315a and on the mesa region 310a, the p-type work function metal layer 750 might otherwise result in the work function for the n-type gate structure 710a being too far away from the conduction band of the material of the nanostructure channels 315a. Accordingly, a masking layer 760 may be formed on the nanostructure channels 315b and on the mesa region 310b, and may be used to remove the p-type work function metal layer 750 from the nanostructure channels 315a and from the mesa region 310a such that the p-type work function metal layer 750 remains on the nanostructure channels 315b and on the mesa region 310b.

A deposition tool may be used to deposit the masking layer 760 on the nanostructure channels 315a and 315b and on the mesa regions 310a and 310b. The masking layer 760 may then be patterned by removing a portion of the masking layer 760 from the nanostructure channels 315a and from the mesa region 310a. An etch tool may be used to etch the masking layer 760 to pattern the masking layer 760. An etch tool may then be used to remove the p-type work function metal layer 750 from the nanostructure channels 315a and from the mesa region 310a while the masking layer 760 protects the nanostructure channels 315b and the mesa region 310b.

As further shown in FIG. 7M, the sacrificial spacers 735 are also removed from the nanostructure channels 315a and from the mesa region 310a. In some implementations, the sacrificial spacers 735 may be removed after removal of the p-type work function metal layer 750 from the nanostructure channels 315a and from the mesa region 310a. For example, a first etch operation may be performed to remove the p-type work function metal layer 750, and then a second etch operation may be performed to remove the sacrificial spacers 735. In some implementations, the sacrificial spacers 735 and the p-type work function metal layer 750 are removed from the nanostructure channels 315a and from the mesa region 310a together in the same etch operation.

In some implementations, a wet etch technique is used to remove the sacrificial spacers 735 from the nanostructure channels 315a and from the mesa region 310a. For example, a basic (or alkaline) wet etchant (e.g., a wet etchant having a pH that is greater than 7), such as ammonium hydroxide (NH₄OH), may be used to isotropically etch the sacrificial spacers 735 to remove the sacrificial spacers 735 from the nanostructure channels 315a and from the mesa region 310a with minimal to no etching of the gate dielectric layer 715 on the nanostructure channels 315a and on the mesa region 310a. The ammonium hydroxide wet etchant includes negatively charged ions (e.g., OH ions) that enable the sacrificial spacers 735 to be isotropically etched because the material of the sacrificial spacers 735 (e.g., aluminum oxide (Al₂O₃), among other examples) may have a positive surface charge that attracts the negatively charged ions in the ammonium hydroxide wet etchant.

The masking layer 760 may be subsequently removed from the nanostructure channels 315b and from the mesa region 310b using a plasma ashing technique (e.g., using a nitrogen (N₂) plasma and a hydrogen (H₂) reactant gas) and/or another type of masking layer removal technique.

As shown in FIG. 7N, the masking layer 760 is fully removed from between adjacent regions of the dielectric layer 605 next to the nanostructure channels 315a. The sacrificial spacer layer 720 being removed (e.g., fully removed) from the sidewalls of the regions of the dielectric layer 605 with minimal to no residual material of the sacrificial spacer layer 720 remaining on the sidewalls of the regions of the dielectric layer 605, as described in connection with FIGS. 7H-7J, prevents or minimizes the likelihood of the p-type work function metal layer 750 merging between adjacent regions of the dielectric layer 605 next to the nanostructure channels 315a. Merging of the p-type work function metal layer 750 between adjacent regions of the dielectric layer 605 next to the nanostructure channels 315a might otherwise increase the likelihood of the material of the masking layer 760 becoming trapped between adjacent regions of the dielectric layer 605 next to the nanostructure channels 315a. The sacrificial spacer layer 720 being removed (e.g., fully removed) from the sidewalls of the regions of the dielectric layer 605 with minimal to no residual material of the sacrificial spacer layer 720 remaining on the sidewalls of the regions of the dielectric layer 605, as described in connection with FIGS. 7H-7J, prevents or minimizes the likelihood of the material of the masking layer 760 becoming trapped between adjacent regions of the dielectric layer 605 next to the nanostructure channels 315a.

As shown in FIG. 7O, one or more n-type work function metal layers are formed on the gate dielectric layer 715 for the n-type gate structure 710a. The one or more n-type work function metal layers may be formed around the nanostructure channels 315a and on the mesa region 310 after the p-type work function metal layer 750 and the sacrificial spacers 735 are removed from the nanostructure channels 315a and from the mesa region 310a. The one or more n-type work function metal layers may include an n-type work function metal layer 765 and/or an n-type work function metal layer 770. The n-type work function metal layers 770 and 765 may include different materials or different material combinations. Alternatively, the n-type work function metal layers 770 and 765 may include the same material and/or the same material combination. The n-type work function metal layers 770 and 765 each include one or more metal materials that tune or adjust the work function of the n-type gate structure 710a near the conduction band of the material of the nanostructure channels 315a. In some implementations, the n-type work function metal layer 765 includes titanium aluminum (TiAl). In some implementations, the n-type work function metal layer 765 includes titanium aluminum carbon (TiAlC). In some implementations, the n-type work function metal layer 770 includes another aluminum-containing metal. In some implementations, another n-type work function metal material is included in the n-type work function metal layer 770.

The n-type work function metal layers 765 and/or 770 are formed such that the n-type work function metal layers 765 and/or 770 wrap around each of the nanostructure channels 315a. The n-type work function metal layers 765 and/or 770 may also be formed on the exposed portion of the mesa region 310a below the nanostructure channels 315a. A deposition tool may be used to deposit the n-type work function metal layers 765 and/or 770 using a CVD technique, a PVD technique, an ALD technique, an electroplating technique, and/or another suitable deposition technique.

In some implementations, the n-type work function metal layer 765 is formed such that the n-type work function metal layer 765 is merged between vertically adjacent nanostructure channels 315a. In some implementations, the n-type work function metal layer 765 is formed such that the n-type work function metal layer 765 is not merged between vertically adjacent nanostructure channels 315a.

As shown in FIG. 7P, a gate electrode layer 775 of the n-type gate structure 710a is formed, and a gate electrode layer 775 of the p-type gate structure 710b is formed. In some implementations, a same gate electrode layer 775 is formed for both the n-type gate structure 710a and the p-type gate structure 710b. In some implementations, separate and electrically isolated gate electrode layers 775 are formed for each of the n-type gate structure 710a and the p-type gate structure 710b. A gate electrode layer 775 may be formed on the n-type work function metal layers 770 and 765 over the nanostructure channels 315a for the n-type gate structure 710a. A gate electrode layer 775 may be formed on the p-type work function metal layer 750 over the nanostructure channels 315b for the p-type gate structure 710b.

The gate electrode layer(s) 775 include one or more metal materials, such as ruthenium (Ru), tungsten (W), cobalt (Co), copper (Cu), and/or molybdenum (Mo), among other examples. A deposition tool may be used to deposit the gate electrode layer(s) 775 using a CVD technique, a PVD technique, an ALD technique, an electroplating technique, and/or another suitable deposition technique. The gate electrode layer(s) 775 may be deposited in one or more deposition operations. In some implementations, a seed layer is first deposited, and the gate electrode layer(s) 775 are deposited on the seed layer. In some implementations, a planarization tool may be used to planarize the gate electrode layer(s) 775 after the gate electrode layer(s) 775 are deposited.

As indicated above, FIGS. 7A-7P are provided as an example. Other examples may differ from what is described with regard to FIGS. 7A-7P.

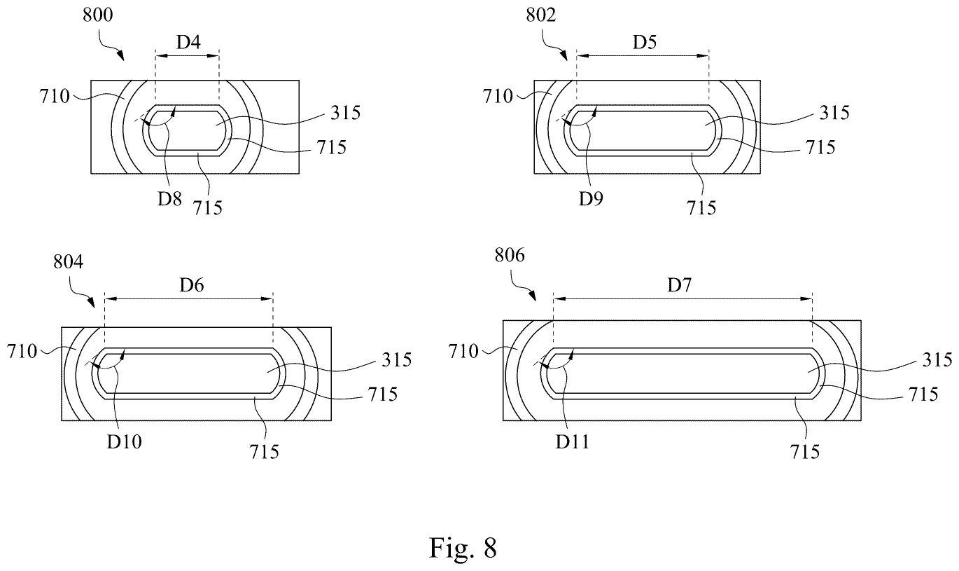

FIG. 8 is a diagram of examples of corner rounding in nanostructure channels of a semiconductor device described herein. As described in connection with FIG. 71, the wet etchant that is used to trim the sacrificial spacer layer 720 to form the sacrificial spacers 735 may also etch the gate dielectric layer 715 on the nanostructure channels 315a and/or on the nanostructure channels 315b. This may result in an amount of corner rounding of the gate dielectric layer 715 at the corners of the nanostructure channels 315a and/or at the corners of the nanostructure channels 315b in the x-direction. FIG. 8 illustrates examples 800, 802, 804, and 806 of corner rounding in a gate dielectric layer 715 for various example sizes of nanostructure channels 315.

In the example 800, a nanostructure channel 315 may have an x-direction width (indicated in FIG. 8 as dimension D4) that is included in a range of approximately 10 nanometers to approximately 12 nanometers. In the example 802, a nanostructure channel 315 may have an x-direction width (indicated in FIG. 8 as a dimension D5) that is included in a range of approximately 17 nanometers to approximately 20 nanometers. In the example 804, a nanostructure channel 315 may have an x-direction width (indicated in FIG. 8 as a dimension D6) that is included in a range of approximately 25 nanometers to approximately 30 nanometers. In the example 806, a nanostructure channel 315 may have an x-direction width (indicated in FIG. 8 as a dimension D7) that is included in a range of approximately 55 nanometers to approximately 60 nanometers.

An angle between a gate dielectric layer 715 on a sidewall of a nanostructure channel 315 and the gate dielectric layer 715 on a top surface or a bottom surface of the nanostructure channel 315 (dimension D8 in the example 800, dimension D9 in the example 802, dimension D10 in the example 804, and dimension D11 in the example 806) may be greater than or approximately equal to 100 degrees. For example, an angle between a gate dielectric layer 715 on a sidewall of a nanostructure channel 315 and the gate dielectric layer 715 on a top surface or a bottom surface of the nanostructure channel 315 may be included in a range of approximately 100 degrees to approximately 160 degrees as a result of the corner rounding that occurs in the corners of the gate dielectric layer 715, due to the use of the wet etchant that is used to trim the sacrificial spacer layer 720 to form the sacrificial spacers 735. However, other values and ranges are within the scope of the present disclosure.

As indicated above, FIG. 8 is provided as an example. Other examples may differ from what is described with regard to FIG. 8.

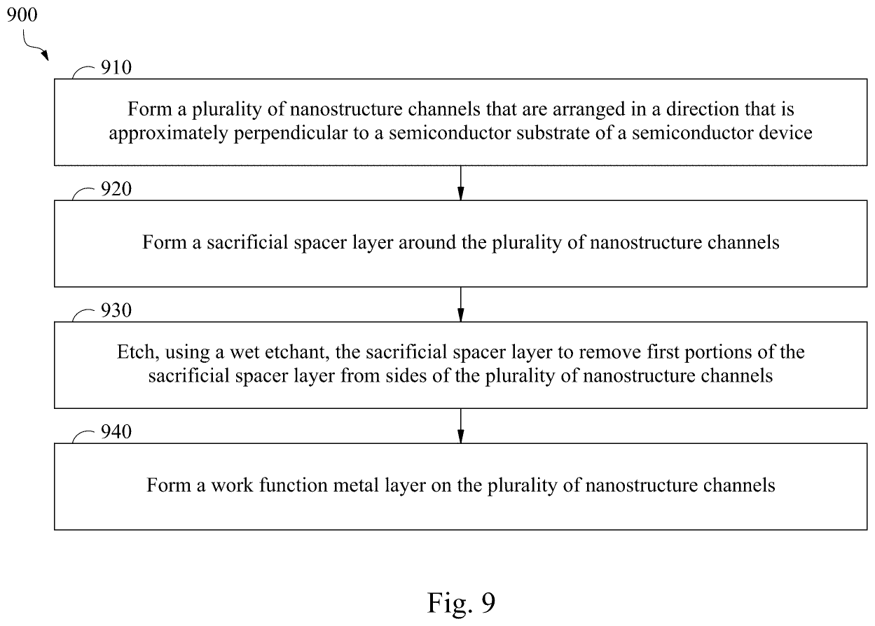

FIG. 9 is a flowchart of an example process 900 associated with semiconductor device described herein. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include forming a plurality of nanostructure channels that are arranged in a direction that is approximately perpendicular to a semiconductor substrate of a semiconductor device (block 910). For example, one or more semiconductor processing tools may be used to form a plurality of nanostructure channels (e.g., nanostructure channels 315, nanostructure channels 315a) that are arranged in a direction (e.g., a z-direction) that is approximately perpendicular to a semiconductor substrate (e.g., a semiconductor substrate 110) of a semiconductor device (e.g., a semiconductor device 105), as described herein.

As further shown in FIG. 9, process 900 may include forming a sacrificial spacer layer around the plurality of nanostructure channels (block 920). For example, one or more semiconductor processing tools may be used to form a sacrificial spacer layer (e.g., a sacrificial spacer layer 720) around the plurality of nanostructure channels, as described herein.

As further shown in FIG. 9, process 900 may include etching, using a wet etchant, the sacrificial spacer layer to remove first portions of the sacrificial spacer layer from sides of the plurality of nanostructure channels (block 930). For example, one or more semiconductor processing tools may be used to etch, using a wet etchant, the sacrificial spacer layer to remove first portions of the sacrificial spacer layer from sides of the plurality of nanostructure channels, as described herein. In some implementations, second portions of the sacrificial spacer layer remain between vertically adjacent nanostructure channels of the plurality of nanostructure channels as sacrificial spacers (e.g., sacrificial spacers 735). In some implementations, hydrogen (H⁺) ions (e.g., positive ions 740) in the wet etchant inhibit etching of the sacrificial spacers between the vertically adjacent nanostructure channels of the plurality of nanostructure channels.

As further shown in FIG. 9, process 900 may include forming a work function metal layer on the plurality of nanostructure channels (block 940). For example, one or more semiconductor processing tools may be used to form a work function metal layer (e.g., a p-type work function metal layer 750) on the plurality of nanostructure channels, as described herein. In some implementations, the sacrificial spacers inhibit formation of the work function metal layer between the vertically adjacent nanostructure channels of the plurality of nanostructure channels.

Process 900 may include additional implementations, such as any single implementation or any combination of implementations described below and/or in connection with one or more other processes described elsewhere herein.

In a first implementation, the sacrificial spacer layer includes a material having a positive surface charge (e.g., a surface charge 745).

In a second implementation, alone or in combination with the first implementation, the wet etchant includes a hydrogen-containing acid.

In a third implementation, alone or in combination with one or more of the first and second implementations, process 900 includes etching the sacrificial spacer layer to reduce a thickness of the sacrificial spacer layer, where etching the sacrificial spacer layer to remove the first portions of the sacrificial spacer layer includes etching the sacrificial spacer layer to remove the first portions of the sacrificial spacer layer after etching the sacrificial spacer layer to reduce the thickness of the sacrificial spacer layer.

In a fourth implementation, alone or in combination with one or more of the first through third implementations, process 900 includes forming a gate dielectric layer (e.g., a gate dielectric layer 715) around the plurality of nanostructure channels, where forming the sacrificial spacer layer includes forming the sacrificial spacer layer on the gate dielectric layer, and etching the sacrificial spacer layer results in etching of corners of the gate dielectric layer.

In a fifth implementation, alone or in combination with one or more of the first through fourth implementations, process 900 includes etching, using the wet etchant, the sacrificial spacer layer to remove third portions of the sacrificial spacer layer from sidewalls of adjacent ILD regions (e.g., adjacent regions of a dielectric layer 605) that are located adjacent to the sides of the plurality of nanostructure channels.

In a sixth implementation, alone or in combination with one or more of the first through fifth implementations, process 900 includes removing the work function metal layer and the sacrificial spacers from the plurality of nanostructure channels, and forming, after removing the work function metal layer and the sacrificial spacers, another work function metal layer (e.g., an n-type work function metal layer 765, an n-type work function metal layer 770) around the plurality of nanostructure channels.

In a seventh implementation, alone or in combination with one or more of the first through sixth implementations, the work function metal layer is a p-type work function metal layer, and the other work function metal layer is an n-type work function metal layer.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

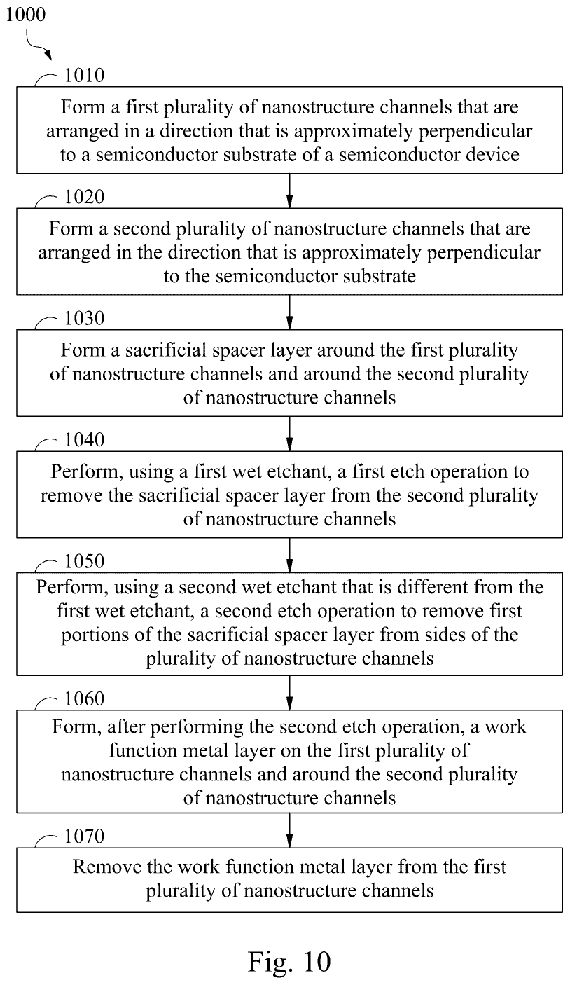

FIG. 10 is a flowchart of an example process 1000 associated with forming a semiconductor device described herein. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming a first plurality of nanostructure channels that are arranged in a direction (z-direction) that is approximately perpendicular to a semiconductor substrate of a semiconductor device (block 1010). For example, one or more semiconductor processing tools may be used to form a first plurality of nanostructure channels (e.g., nanostructure channels 315a) that are arranged in a direction (e.g., a z-direction) that is approximately perpendicular to a semiconductor substrate (e.g., a semiconductor substrate 110) of a semiconductor device (e.g., a semiconductor device 105), as described herein.

As further shown in FIG. 10, process 1000 may include forming a second plurality of nanostructure channels that are arranged in the direction that is approximately perpendicular to the semiconductor substrate (block 1020). For example, one or more semiconductor processing tools may be used to form a second plurality of nanostructure channels (e.g., nanostructure channels 315b) that are arranged in the direction that is approximately perpendicular to the semiconductor substrate, as described herein.

As further shown in FIG. 10, process 1000 may include forming a sacrificial spacer layer around the first plurality of nanostructure channels and around the second plurality of nanostructure channels (block 1030). For example, one or more semiconductor processing tools may be used to form a sacrificial spacer layer (e.g., a sacrificial spacer layer 720) around the first plurality of nanostructure channels and around the second plurality of nanostructure channels, as described herein.

As further shown in FIG. 10, process 1000 may include performing, using a first wet etchant, a first etch operation to remove the sacrificial spacer layer from the second plurality of nanostructure channels (block 1040). For example, one or more semiconductor processing tools may be used to perform, using a first wet etchant, a first etch operation to remove the sacrificial spacer layer from the second plurality of nanostructure channels, as described herein.

As further shown in FIG. 10, process 1000 may include performing, using a second wet etchant that is different from the first wet etchant, a second etch operation to remove first portions of the sacrificial spacer layer from sides of the plurality of nanostructure channels (block 1050). For example, one or more semiconductor processing tools may be used to perform, using a second wet etchant that is different from the first wet etchant, a second etch operation to remove first portions of the sacrificial spacer layer from sides of the plurality of nanostructure channels, as described herein. In some implementations, second portions of the sacrificial spacer layer remain between vertically adjacent nanostructure channels of the first plurality of nanostructure channels as sacrificial spacers (e.g., sacrificial spacers 735). In some implementations, seams (e.g., seams 725) are located between vertically adjacent sacrificial spacers that are between the vertically adjacent nanostructure channels. In some implementations, a combination of hydrogen (H⁺) ions (e.g., positive ions 740) in the second wet etchant and a material of the sacrificial spacers inhibits increasing of a vertical width (e.g., dimension D1, dimension D2) of the seams during the second etch operation.

As further shown in FIG. 10, process 1000 may include forming, after performing the second etch operation, a work function metal layer on the first plurality of nanostructure channels and around the second plurality of nanostructure channels (block 1060). For example, one or more semiconductor processing tools may be used to form, after performing the second etch operation, a work function metal layer (e.g., a p-type work function metal layer 750) on the first plurality of nanostructure channels and around the second plurality of nanostructure channels, as described herein. In some implementations, the sacrificial spacers inhibit formation of the work function metal layer between the vertically adjacent nanostructure channels of the first plurality of nanostructure channels.

As further shown in FIG. 10, process 1000 may include removing the work function metal layer from the first plurality of nanostructure channels (block 1070). For example, one or more semiconductor processing tools may be used to remove the work function metal layer from the first plurality of nanostructure channels, as described herein.

Process 1000 may include additional implementations, such as any single implementation or any combination of implementations described below and/or in connection with one or more other processes described elsewhere herein.

In a first implementation, the first wet etchant includes a basic wet etchant, and the second wet etchant includes an acidic wet etchant.

In a second implementation, alone or in combination with the first implementation, the second wet etchant includes at least one of hydrofluoric acid (HF), hydrochloric acid (HCl), sulfuric acid (H₂SO₄), hydrobromic acid (HBr), or carbon dioxide (CO₂) dissolved in water (H₂O).

In a third implementation, alone or in combination with one or more of the first and second implementations, process 1000 includes forming a high-k gate dielectric layer (e.g., a gate dielectric layer 715) around the first plurality of nanostructure channels, where forming the sacrificial spacer layer includes forming the sacrificial spacer layer on the high-k gate dielectric layer, and the second etch operation results in rounding of corners of the high-k gate dielectric layer.

In a fourth implementation, alone or in combination with one or more of the first through third implementations, the work function metal layer is a first type work function metal layer, and the process 1000 includes forming, after removing the work function metal layer from the first plurality of nanostructure channels, a second type work function metal layer (e.g., an n-type work function metal layer 765, an n-type work function metal layer 770) around the first plurality of nanostructure channels.

In a fifth implementation, alone or in combination with one or more of the first through fourth implementations, process 1000 includes removing the sacrificial spacers from the first plurality of nanostructure channels after removing the work function metal layer from the first plurality of nanostructure channels, where forming the second type work function metal layer includes removing the second type work function metal layer after removing the sacrificial spacers.

In a sixth implementation, alone or in combination with one or more of the first through fifth implementations, performing the second etch operation includes performing, using the second wet etchant, the second etch operation to remove third portions of the sacrificial spacer layer from sidewalls of adjacent ILD regions (e.g., adjacent regions of a dielectric layer 605) that are located adjacent to the sides of the first plurality of nanostructure channels.

In a seventh implementation, alone or in combination with one or more of the first through sixth implementations, forming the work function metal layer includes forming the work function metal layer on the sidewalls of the adjacent ILD regions, wherein portions of the work function metal layer on the sidewalls of the adjacent ILD regions are physically separated by a gap (e.g., a dimension D3) between the adjacent ILD regions.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, sacrificial spacers are formed between vertically adjacent nanostructure channels of a first nanostructure transistor to prevent or reduce the likelihood of material from a work function metal layer of a second nanostructure transistor being deposited between the vertically adjacent nanostructure channels. The sacrificial spacers may be formed by depositing a conformal sacrificial spacer layer around the nanostructure channels of the first nanostructure channel, and then etching the sacrificial spacer layer such that the sacrificial spacer layer remains only between vertically adjacent nanostructure channels of the first nanostructure transistor as the sacrificial spacers. In some cases, seams may form in the sacrificial spacer layer between vertically adjacent nanostructure channels. An anisotropic wet etch technique described herein may be used to etch the sacrificial spacer layer such that the seams are not widened (or are minimally widened) by the etching, which might otherwise increase the likelihood of the material of the work function metal layer of the second nanostructure transistor being deposited in the seams between the vertically adjacent nanostructure channels. Thus, the anisotropic wet etch technique described herein may increase the likelihood that the material of the work function metal layer of the second nanostructure transistor will be fully removed from the first nanostructure transistor prior to formation of a work function metal layer of the second nanostructure transistor.

As described in greater detail herein, some implementations described herein include a method. The method includes forming a plurality of nanostructure channels that are arranged in a direction that is approximately perpendicular to a semiconductor substrate of a semiconductor device. The method includes forming a sacrificial spacer layer around the plurality of nanostructure channels. The method includes etching, using a wet etchant, the sacrificial spacer layer to remove first portions of the sacrificial spacer layer from sides of the plurality of nanostructure channels. Second portions of the sacrificial spacer layer remain between vertically adjacent nanostructure channels of the plurality of nanostructure channels as sacrificial spacers. Hydrogen (H⁺) ions in the wet etchant inhibit etching of the sacrificial spacers between the vertically adjacent nanostructure channels of the plurality of nanostructure channels. The method includes forming a work function metal layer on the plurality of nanostructure channels. The sacrificial spacers inhibit formation of the work function metal layer between the vertically adjacent nanostructure channels of the plurality of nanostructure channels.

As described in greater detail herein, some implementations described herein include a method. The method includes forming a first plurality of nanostructure channels that are arranged in a direction that is approximately perpendicular to a semiconductor substrate of a semiconductor device. The method includes forming a second plurality of nanostructure channels that are arranged in the direction that is approximately perpendicular to the semiconductor substrate. The method includes forming a sacrificial spacer layer around the first plurality of nanostructure channels and around the second plurality of nanostructure channels. The method includes removing the sacrificial spacer layer from the second plurality of nanostructure channels and removing first portions of the sacrificial spacer layer from sides of the first plurality of nanostructure channels. Second portions of the sacrificial spacer layer remain between vertically adjacent nanostructure channels of the first plurality of nanostructure channels as sacrificial spacers. Seams are located between vertically adjacent sacrificial spacers that are between the vertically adjacent nanostructure channels. A combination of hydrogen (H⁺) ions in the second wet etchant and a material of the sacrificial spacers inhibits increasing of a vertical width of the seams during the second etch operation. The method includes forming, after performing the second etch operation, a work function metal layer on the first plurality of nanostructure channels and around the second plurality of nanostructure channels. The sacrificial spacers inhibit formation of the work function metal layer between the vertically adjacent nanostructure channels of the first plurality of nanostructure channels. The method includes removing the work function metal layer from the first plurality of nanostructure channels.

As described in greater detail herein, some implementations described herein include a semiconductor device. The semiconductor device includes a first plurality of nanostructure channels arranged in a first direction that is approximately perpendicular to a semiconductor substrate of the semiconductor device. The semiconductor device includes a second plurality of nanostructure channels, adjacent to the first plurality of nanostructure channels in a second direction, that are arranged in the first direction that is approximately perpendicular to the semiconductor substrate. The first plurality of nanostructure channels and the second plurality of nanostructure channels extend in a third direction that is approximately perpendicular to the second direction. The semiconductor device includes a first gate structure, wrapping around the first plurality of nanostructure channels, comprising a first type work function metal layer. The semiconductor device includes a first gate dielectric layer between the first gate structure and the first plurality of nanostructure channels. In the third direction, an angle between a first portion of the first gate dielectric layer on a sidewall of a nanostructure channel of the first plurality of nanostructure channels, and a second portion of the first gate dielectric layer on a top surface of the nanostructure channel, is greater than or approximately equal to 100 degrees. The semiconductor device includes a second gate structure, wrapping around each of the second plurality of nanostructure channels, comprising a second type work function metal layer different from the first type work function metal layer. The semiconductor device includes a second gate dielectric layer between the second gate structure and the second plurality of nanostructure channels.

The terms “approximately” and “substantially” can indicate a value of a given quantity that varies within 5% of the value (e.g., +1%, +2%, +3%, +4%, +5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of nanostructure channels that are arranged in a direction that is approximately perpendicular to a semiconductor substrate of a semiconductor device;
forming a sacrificial spacer layer around the plurality of nanostructure channels;
etching, using a wet etchant, the sacrificial spacer layer to remove first portions of the sacrificial spacer layer from sides of the plurality of nanostructure channels,
wherein second portions of the sacrificial spacer layer remain between vertically adjacent nanostructure channels of the plurality of nanostructure channels as sacrificial spacers, and
wherein hydrogen (H⁺) ions in the wet etchant inhibit etching of the sacrificial spacers between the vertically adjacent nanostructure channels of the plurality of nanostructure channels; and
forming a work function metal layer on the plurality of nanostructure channels,
wherein the sacrificial spacers inhibit formation of the work function metal layer between the vertically adjacent nanostructure channels of the plurality of nanostructure channels.

2. The method of claim 1, wherein the sacrificial spacer layer comprises a material having a positive surface charge.

3. The method of claim 1, wherein the wet etchant comprises a hydrogen-containing acid.

4. The method of claim 1, further comprising:
etching the sacrificial spacer layer to reduce a thickness of the sacrificial spacer layer,
wherein etching the sacrificial spacer layer to remove the first portions of the sacrificial spacer layer comprises:
etching the sacrificial spacer layer to remove the first portions of the sacrificial spacer layer after etching the sacrificial spacer layer to reduce the thickness of the sacrificial spacer layer.

5. The method of claim 1, further comprising:
forming a gate dielectric layer around the plurality of nanostructure channels,
wherein forming the sacrificial spacer layer comprises:
forming the sacrificial spacer layer on the gate dielectric layer, and
wherein etching the sacrificial spacer layer results in etching of corners of the gate dielectric layer.

6. The method of claim 1, further comprising:
etching, using the wet etchant, the sacrificial spacer layer to remove third portions of the sacrificial spacer layer from sidewalls of adjacent interlayer dielectric (ILD) regions that are located adjacent to the sides of the plurality of nanostructure channels.

7. The method of claim 1, further comprising:
removing the work function metal layer and the sacrificial spacers from the plurality of nanostructure channels; and
forming, after removing the work function metal layer and the sacrificial spacers, another work function metal layer around the plurality of nanostructure channels.

8. The method of claim 7, wherein the work function metal layer is a p-type work function metal layer; and
wherein the other work function metal layer is an n-type work function metal layer.

9. A method, comprising:
forming a first plurality of nanostructure channels that are arranged in a direction that is approximately perpendicular to a semiconductor substrate of a semiconductor device;
forming a second plurality of nanostructure channels that are arranged in the direction that is approximately perpendicular to the semiconductor substrate;
forming a sacrificial spacer layer around the first plurality of nanostructure channels and around the second plurality of nanostructure channels;
removing the sacrificial spacer layer from the second plurality of nanostructure channels and removing first portions of the sacrificial spacer layer from sides of the first plurality of nanostructure channels;
wherein second portions of the sacrificial spacer layer remain between vertically adjacent nanostructure channels of the first plurality of nanostructure channels as sacrificial spacers,
wherein seams are located between vertically adjacent sacrificial spacers that are between the vertically adjacent nanostructure channels, and
wherein a combination of hydrogen (H⁺) ions in the second wet etchant and a material of the sacrificial spacers inhibits increasing of a vertical width of the seams during the second etch operation;
forming, after performing the second etch operation, a work function metal layer on the first plurality of nanostructure channels and around the second plurality of nanostructure channels,
wherein the sacrificial spacers inhibit formation of the work function metal layer between the vertically adjacent nanostructure channels of the first plurality of nanostructure channels; and
removing the work function metal layer from the first plurality of nanostructure channels.

10. The method of claim 9, wherein the first wet etchant comprises a basic wet etchant; and
wherein the second wet etchant comprises an acidic wet etchant selected from at least one of:
hydrofluoric acid (HF),
hydrochloric acid (HCl),
sulfuric acid (H₂SO₄),
hydrobromic acid (HBr), or
carbon dioxide (CO₂) dissolved in water (H₂O).

11. The method of claim 9, further comprising:
forming a high dielectric constant (high-k) gate dielectric layer around the first plurality of nanostructure channels,
wherein forming the sacrificial spacer layer comprises:
forming the sacrificial spacer layer on the high-k gate dielectric layer, and
wherein the second etch operation results in rounding of corners of the high-k gate dielectric layer.

12. The method of claim 9, wherein the work function metal layer is a first type work function metal layer; and
wherein the method further comprises:
forming, after removing the work function metal layer from the first plurality of nanostructure channels, a second type work function metal layer around the first plurality of nanostructure channels.

13. The method of claim 12, further comprising:
removing the sacrificial spacers from the first plurality of nanostructure channels after removing the work function metal layer from the first plurality of nanostructure channels,
wherein forming the second type work function metal layer comprises:
removing the second type work function metal layer after removing the sacrificial spacers.

14. The method of claim 9, wherein performing the second etch operation comprises:
performing, using the second wet etchant, the second etch operation to remove third portions of the sacrificial spacer layer from sidewalls of adjacent interlayer dielectric (ILD) regions that are located adjacent to the sides of the first plurality of nanostructure channels.

15. The method of claim 14, wherein forming the work function metal layer comprises:
forming the work function metal layer on the sidewalls of the adjacent ILD regions,
wherein portions of the work function metal layer on the sidewalls of the adjacent ILD regions are physically separated by a gap between the adjacent ILD regions.

16. The method of claim 9, wherein removing the sacrificial spacer layer from the second plurality of nanostructure channels comprises performing, using a first wet etchant, a first etch operation to remove the sacrificial spacer layer from the second plurality of nanostructure channels; and
wherein removing first portions of the sacrificial spacer layer from sides of the plurality of nanostructure channels comprises performing, using a second wet etchant that is different from the first wet etchant, a second etch operation to remove first portions of the sacrificial spacer layer from sides of the plurality of nanostructure channels.

17. A semiconductor device, comprising:
a first plurality of nanostructure channels arranged in a first direction that is approximately perpendicular to a semiconductor substrate of the semiconductor device;
a second plurality of nanostructure channels, adjacent to the first plurality of nanostructure channels in a second direction, that are arranged in the first direction that is approximately perpendicular to the semiconductor substrate,
wherein the first plurality of nanostructure channels and the second plurality of nanostructure channels extend in a third direction that is approximately perpendicular to the second direction;
a first gate structure, wrapping around the first plurality of nanostructure channels, comprising a first type work function metal layer;
a first gate dielectric layer between the first gate structure and the first plurality of nanostructure channels,
wherein, in the third direction, an angle between a first portion of the first gate dielectric layer on a sidewall of a nanostructure channel of the first plurality of nanostructure channels, and a second portion of the first gate dielectric layer on a top surface of the nanostructure channel, is greater than or approximately equal to 100 degrees;
a second gate structure, wrapping around each of the second plurality of nanostructure channels, comprising a second type work function metal layer different from the first type work function metal layer; and
a second gate dielectric layer between the second gate structure and the second plurality of nanostructure channels.

18. The semiconductor device of claim 17, wherein the angle between the first portion of the first gate dielectric layer and the second portion of the first gate dielectric layer is included in a range of approximately 100 degrees to approximately 160 degrees.

19. The semiconductor device of claim 17, wherein, in the third direction, another angle between a first portion of the second gate dielectric layer on a sidewall of another nanostructure channel of the second plurality of nanostructure channels, and a second portion of the second gate dielectric layer on a top surface of the other nanostructure channel, is greater than or approximately equal to 100 degrees.

20. The semiconductor device of claim 19, wherein the angle between the first portion of the second gate dielectric layer and the second portion of the second gate dielectric layer is included in a range of approximately 100 degrees to approximately 160 degrees.
